(19) United States
(12) Patent Application Publication
(10) Pub. No.: US 2024/0243020 A1
(43) Pub. Date: Jul. 18, 2024

(54) VERTICAL NON-VOLATILE MEMORY DEVICE

(71) Applicant: SAMSUNG ELECTRONICS CO., LTD., Suwon-si (KR)

(72) Inventors: Shinhwan KANG, Suwon-si (KR); Sunyoung Lee, Suwon-si (KR)

(21) Appl. No.: 18/535,095

(22) Filed: Dec. 11, 2023

(30) Foreign Application Priority Data
Jan. 13, 2023 (KR) 10-2023-0005476

(51) Int. Cl. H01L 21/66; H10B 41/27; H10B 41/41; H10B 43/27; H10B 43/40

(52) U.S. Cl. CPC H01L 22/32; H10B 41/27; H10B 41/41; H10B 43/27; H10B 43/40

(57) ABSTRACT

A vertical non-volatile memory device, including a memory cell region including a plurality of gate lines overlapping each other in a vertical direction, and an insulating layer insulating the plurality of gate lines from each other in the vertical direction, an extension region on one side of the memory cell region, the extension region including a plurality of stepped connection portions having a plurality of raised pads integrally connected to each of the plurality of gate lines, a peripheral circuit structure in a lower portion of the memory cell region and the extension region, the peripheral circuit structure including a peripheral circuit wiring layer, a through type cell contact pattern in the extension region penetrating the plurality of gate lines, the insulating layer, and the plurality of stepped connection portions, and a through type cell contact monitoring pattern in the extension region spaced from the through type cell contact pattern.

### CROSS-REFERENCE TO RELATED APPLICATION

Korean Patent Application No. 10-2023-0005476, filed on Jan. 13, 2023, in the Korean Intellectual Property Office, is incorporated by reference herein in its entirety.

### BACKGROUND

### 1. Field

A vertical non-volatile memory device is disclosed.

### 2. Description of the Related Art

In an electronic system requiring data storage, a semiconductor device capable of storing high-capacity data is required.

### SUMMARY

Embodiments are directed to a vertical non-volatile memory device, including a memory cell region including a plurality of gate lines overlapping each other in a vertical direction, and an insulating layer insulating the plurality of gate lines from each other in the vertical direction, an extension region on one side of the memory cell region, the extension region including a plurality of stepped connection portions having a plurality of raised pads integrally connected to each of the plurality of gate lines, a peripheral circuit structure in a lower portion of the memory cell region and the extension region, the peripheral circuit structure including a peripheral circuit wiring layer, a through type cell contact pattern in the extension region penetrating the plurality of gate lines, the insulating layer, and the plurality of stepped connection portions, and a through type cell contact monitoring pattern in the extension region spaced from the through type cell contact pattern, the through type cell contact monitoring pattern monitoring the through type cell contact pattern.

Embodiments are directed to a vertical non-volatile memory device, including a peripheral circuit structure including a peripheral circuit wiring layer, a cell array structure on the peripheral circuit structure, the cell array structure including a memory cell region and an extension region, wherein the memory cell region includes a plurality of gate lines overlapping each other in a vertical direction, and an insulating layer insulating the plurality of gate lines from each other in the vertical direction, the extension region being on one side of the memory cell region, the extension region including a plurality of stepped connection portions having a plurality of raised pads integrally connected to each of the plurality of gate lines, a through type cell contact pattern in the extension region, the through type cell contact pattern penetrating the plurality of gate lines, the insulating layer, and the plurality of stepped connection portions, and a through type cell contact monitoring pattern in the extension region away from the through type cell contact pattern, the through type cell contact monitoring pattern monitoring the through type cell contact pattern.

Embodiments are directed to a vertical non-volatile memory device, including a peripheral circuit structure on a lower substrate, the peripheral circuit structure including a peripheral circuit wiring layer, a cell array structure on the peripheral circuit structure, the cell array structure including a memory cell region and an extension region on an upper substrate, wherein the memory cell region includes a plurality of gate lines overlapping each other in a vertical direction on the upper substrate, and an insulating layer insulating the plurality of gate lines from each other in the vertical direction, the extension region being on one side of the memory cell region, the extension region including a plurality of stepped connection portions having a plurality of raised pads integrally connected to each of the plurality of gate lines, a through type cell contact pattern in the extension region, the through type cell contact pattern penetrating the plurality of gate lines, the insulating layer, the plurality of stepped connection portions, and the upper substrate, and a through type cell contact monitoring pattern in the extension region away from the through type cell contact pattern, the through type cell contact monitoring pattern monitoring the through type cell contact pattern.

### BRIEF DESCRIPTION OF THE DRAWINGS

Features will become apparent to those of skill in the art by describing in detail exemplary embodiments with reference to the attached drawings in which:

FIG. 1 is a block diagram showing a vertical non-volatile memory device according to an example embodiment.

FIG. 2 is a perspective view showing a vertical non-volatile memory device according to an example embodiment.

FIG. 3 is a circuit diagram showing a memory cell array of a vertical non-volatile memory device according to an example embodiment.

FIG. 4 is a plan view showing a vertical non-volatile memory device according to an example embodiment.

FIG. 5 shows a vertical non-volatile memory device according to an example embodiment.

FIG. 6 is a cross-sectional view taken along line Y1-Y1′ of FIG. 5.

FIG. 7 is a view showing an enlarged portion “EX1” of FIG. 6 according to an example embodiment.

FIG. 8 is a cross-sectional view taken along line X1-X1′ of FIG. 5.

FIG. 9 is a cross-sectional view taken along line X2-X2′ of FIG. 5.

FIG. 10 is a diagram showing an electron beam inspection device according to an example embodiment.

FIG. 11 is a plan view showing components of the memory cell blocks BLK11 and BLK12 of FIG. 4.

FIG. 12 is a cross-sectional view taken along line X2-X2′ of FIG. 11.

FIG. 13 is a plan view showing components of the memory cell blocks BLK11 and BLK12 of FIG. 4.

FIG. 14 is a cross-sectional view taken along line X2-X2′ of FIG. 13.

FIG. 15 is a view showing an enlarged portion “EX1” of FIG. 6 according to an example embodiment.

FIG. 16 is a view showing an enlarged portion “EX1” of FIG. 6 according to an example embodiment.

FIG. 17 is a view showing an enlarged portion “EX1” of FIG. 6 according to an example embodiment.

FIG. 18 is a partial plan view showing a vertical non-volatile memory device according to an example embodiment.

FIG. 19 is a partial plan view showing an extension region “EXT” of FIG. 18 according to an example embodiment.

FIG. 20 is a diagram showing an electronic system including a vertical non-volatile memory device according to an example embodiment.

FIG. 21 is a perspective view showing an electronic system including a vertical non-volatile memory device according to an example embodiment.

FIG. 22 is a cross-sectional view taken along line II-II′ of FIG. 21.

FIG. 23 is a cross-sectional view taken along line II-II′ of FIG. 21.

### DETAILED DESCRIPTION

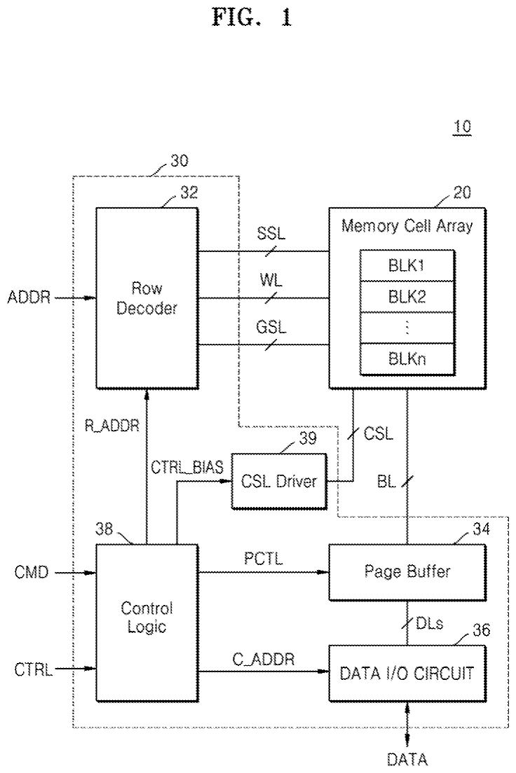

FIG. 1 is a block diagram showing a vertical non-volatile memory device according to an example embodiment. In an implementation, a vertical non-volatile memory device 10 may continuously maintain stored data even when power is not supplied. The vertical non-volatile memory device 10 may be a vertical NAND flash memory device.

The vertical non-volatile memory device 10 may include a memory cell array 20 and a peripheral circuit 30. The memory cell array 20 may include a plurality of memory cell blocks BLK1, BLK2, BLKn (where n is a positive integer). Each of the plurality of memory cell blocks BLK1, BLK2, BLKn may include a plurality of memory cells. The memory cell blocks BLK1, BLK2, BLKn may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, a control logic 38, and a common source line (CSL) driver 39. The peripheral circuit 30 may further include various circuits such as a voltage generation circuit generating various voltages necessary for the operation of the vertical non-volatile memory device 10, an error correction circuit correcting errors in data read from the memory cell array 20, and an input/output interface.

The memory cell array 20 may be connected to the page buffer 34 through the bit line BL. The memory cell array 20 may be connected to the row decoder 32 through the word line WL, the string selection line SSL, and the ground selection line GSL. In the memory cell array 20, the plurality of memory cells included in each of the plurality of memory cell blocks BLK1, BLK2, BLKn may be flash memory cells. The memory cell array 20 may include a three-dimensional (3D) memory cell array. The 3D memory cell array may include a plurality of NAND strings. Each of the plurality of NAND strings may include a plurality of memory cells respectively connected to a plurality of vertically stacked word lines WL.

The peripheral circuit 30 may receive an address ADDR, a command CMD, and a control signal CTRL from the outside of the vertical non-volatile memory device 10 and may transmit/receive data DATA to and from an apparatus outside the vertical non-volatile memory device 10.

The row decoder 32 may select at least one of the plurality of memory cell blocks BLK1, BLK2, BLKn in response to the address ADDR from the outside, and may select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to sense the data DATA stored in the memory cell array 20. The page buffer 34 may operate according to a control signal PCTL provided from the control logic 38.

The data I/O circuit 36 may be connected to the page buffer 34 through a plurality of data lines DLs. The data I/O circuit 36 may receive data DATA from a memory controller during a program operation and may provide the program data DATA to the page buffer 34 based on a column address C_ADDR provided from the control logic 38. The data I/O circuit 36 may provide the read data DATA stored in the page buffer 34 to the memory controller based on the column address C_ADDR provided from the control logic 38 during a read operation.

The data I/O circuit 36 may transmit an input address or command to the control logic 38 or the row decoder 32. The peripheral circuit 30 may further include an electrostatic discharge (ESD) circuit and a pull-up/pull-down driver. As used herein, the term “or” is not an exclusive term, e.g., “A or B” would include A, B, or A and B.

The control logic 38 may receive a command CMD and a control signal CTRL from the memory controller. The control logic 38 may provide a row address R_ADDR to the row decoder 32 and provide the column address C_ADDR to the data I/O circuit 36. The control logic 38 may generate various internal control signals used in the vertical non-volatile memory device 10 in response to the control signal CTRL. In an implementation, the control logic 38 may adjust the voltage level provided to the word line WL and the bit line BL when a memory operation such as a program operation or an erase operation is performed.

The common source line driver 39 may be connected to the memory cell array 20 through a common source line CSL. The common source line driver 39 may apply a common source voltage (e.g., a power supply voltage) or a ground voltage to the common source line CSL based on a control signal CTRL_BIAS of the control logic 38. In some embodiments, the common source line driver 39 may be disposed at a lower portion of the memory cell array 20. The common source line driver 39 may vertically overlap at least a part of the memory cell array 20.

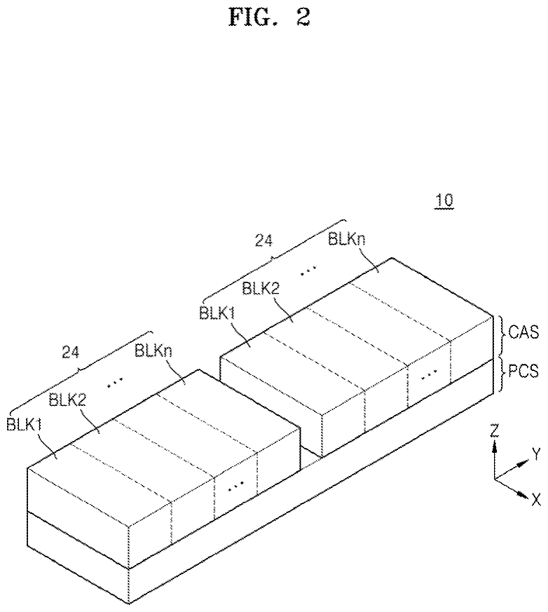

FIG. 2 is a perspective view showing a vertical non-volatile memory device according to an example embodiment. In an implementation, a vertical non-volatile memory device 10 may include a cell array structure CAS and a peripheral circuit structure PCS overlapping each other in a vertical direction (Z direction). The X direction or −X direction may be referred to as a first horizontal direction. The Y direction or −Y direction may be referred to as a second horizontal direction.

In FIG. 2, the cell array structure CAS may be stacked on the peripheral circuit structure PCS in the vertical direction (Z direction), but the peripheral circuit structure PCS may be on one side of the cell array structure CAS in the horizontal direction (X direction) as needed.

The cell array structure CAS may include the memory cell array 20 of FIG. 1. The peripheral circuit structure PCS may include the peripheral circuit 30 of FIG. 1. The cell array structure CAS of FIG. 2 may include a plurality of tiles 24. Each of the tiles 24 may include the plurality of memory cell blocks BLK1, BLK2, BLKn (where n is a positive integer). Each of the memory cell blocks BLK1, BLK2, BLKn may include a plurality of 3D arranged memory cells.

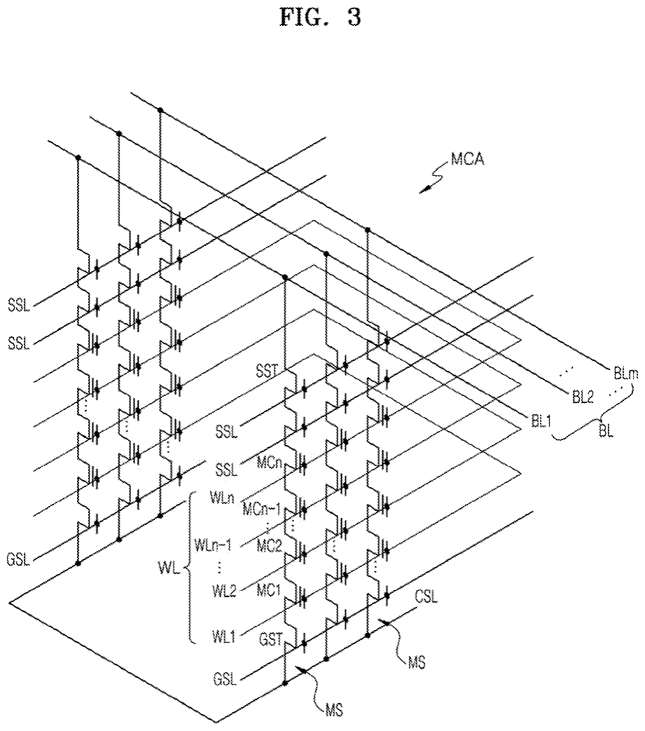

FIG. 3 is a circuit diagram showing a memory cell array of a vertical non-volatile memory device according to an example embodiment. In an implementation, FIG. 3 may be an equivalent circuit diagram of the memory cell array MCA of the vertical non-volatile memory device 10 described above, e.g., a vertical NAND flash memory device. Each of the memory cell blocks BLK1, BLK2, BLKn of FIG. 2 may include the memory cell array MCA having the circuit configuration illustrated in FIG. 3.

The memory cell array MCA may include a plurality of memory cell strings MS. The memory cell array MCA may include a plurality of bit lines BL:BL1, BL2, BLm (where m is a positive integer), a plurality of word lines WL:WL1, WL2, WLn−1, WLn (where n is a positive integer), at least one string selection line SSL, at least one ground selection line GSL, and the common source line CSL.

The plurality of memory cell strings MS may be between the plurality of bit lines BL and the common source lines CSL. FIG. 3 illustrates that each of the plurality of memory cell strings MS may include two string selection lines SSL. In an implementation, each of the plurality of memory cell strings MS may include one string selection line SSL.

Each of the plurality of memory cell strings MS may include a string select transistor SST, a ground select transistor GST, and a plurality of memory cell transistors MC1, MC2, MCn−1, MCn (where n is a positive integer). The memory cell transistors MC1, MC2, MCn−1, MCn may be memory cells.

A drain region of the string select transistor SST may be connected to the bit line BL, and a source region of the ground select transistor GST may be connected to the common source line CSL. The common source line CSL may be a region to which source regions of the plurality of ground selection transistors GST are commonly connected.

The string select transistor SST may be connected to the string selection line SSL, and the ground select transistor GST may be connected to the ground selection line GSL. Each of the plurality of memory cell transistors MC1, MC2, MCn−1, MCn, (where n is a positive integer), may be connected to a plurality of word lines WL.

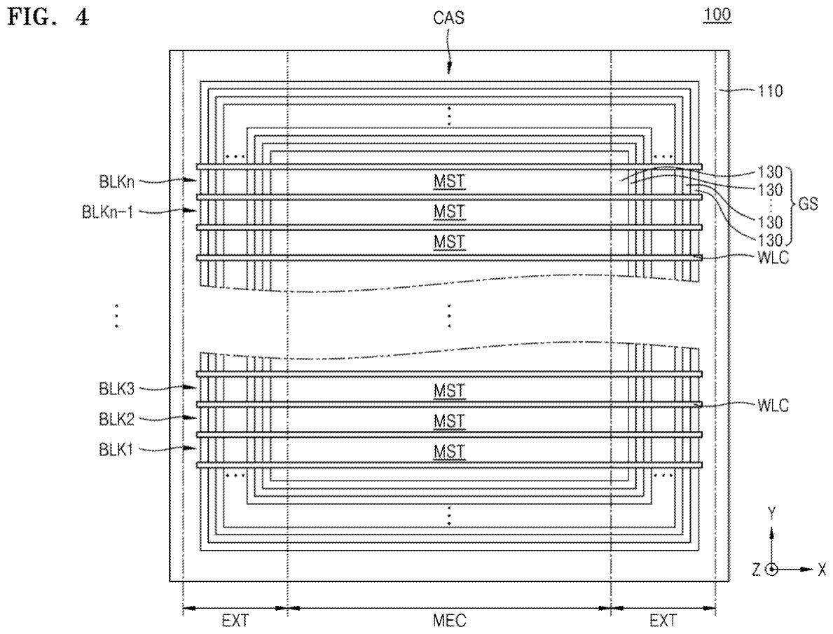

FIG. 4 is a plan view showing a vertical non-volatile memory device according to an example embodiment. In an implementation, the cell array structure CAS of the vertical non-volatile memory device 100 may include an upper substrate 110 and the plurality of memory cell blocks BLK1, BLK2, BLKn-1, BLKn (where n is a positive integer) on the upper substrate 110.

The cell array structure CAS may include a memory cell region MEC and extension regions EXT on both sides of the memory cell region MEC in a first horizontal direction (X direction). The extension region EXT may be referred to as a connection region. Each of the plurality of memory cell blocks BLK1, BLK2, BLKn-1, BLKn may include a memory stack structure MST extending in the first horizontal direction (X direction) across the memory cell region MEC and the extension region EXT.

The memory stack structure MST may include a plurality of gate lines 130 stacked to overlap each other in the vertical direction (Z direction) in the memory cell region MEC and the extension region EXT on the upper substrate 110. The plurality of gate lines 130 may respectively constitute a gate stack GS in a plurality of memory stack structures MST. The gate line 130 may correspond to the word line WL described above with reference to FIGS. 1 and 3.

Each of the plurality of memory stack structures MST may include a plurality of memory stacks at different vertical levels in the vertical direction (Z direction) and overlapping each other in the vertical direction (Z direction). Each of the plurality of memory stacks may include a plurality of gate lines 130 overlapping each other in the vertical direction (Z direction). In some embodiments, each of the plurality of memory stacks may include 48, 64, or 96 gate lines 130 stacked to overlap each other in the vertical direction (Z direction).

In some embodiments, the areas of the plurality of gate lines 130 included in the plurality of memory stack structures MST may gradually decrease as the distance from the upper substrate 110 increases. A central part of each of the plurality of gate lines 130 overlapping each other in the vertical direction (Z direction) may constitute the memory cell region MEC, and an edge part of each of the plurality of gate lines 130 may constitute the extension region EXT.

A plurality of word line cut structures WLC extending in the first horizontal direction (X direction) from the memory cell region MEC and the extension region EXT may be on the upper substrate 110. The plurality of word line cut structures WLC may be spaced apart from each other in a second horizontal direction (Y direction). The plurality of memory cell blocks BLK1, BLK2, BLKn-1, BLKn may be between each of the plurality of word line cut structures WLC.

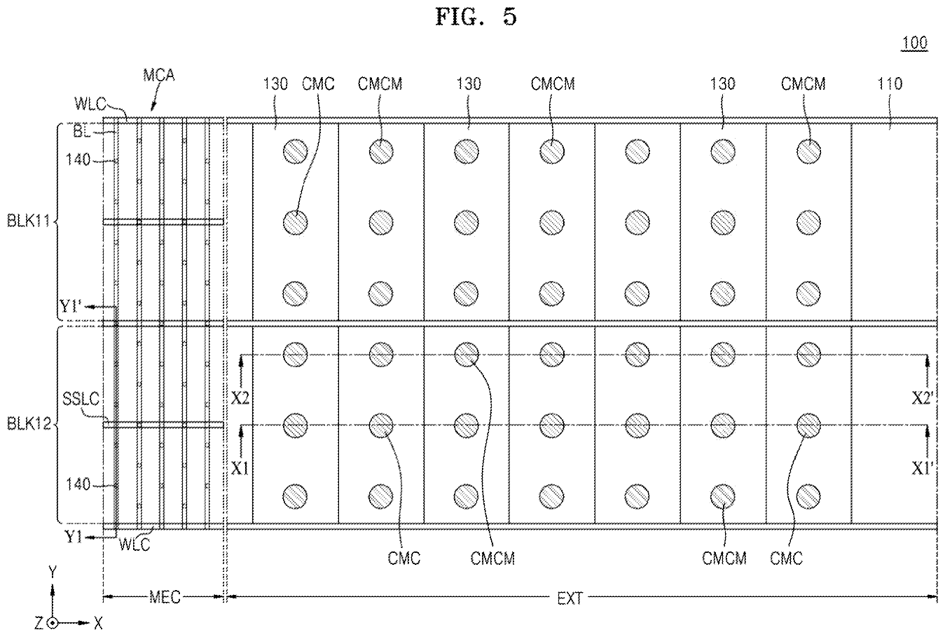

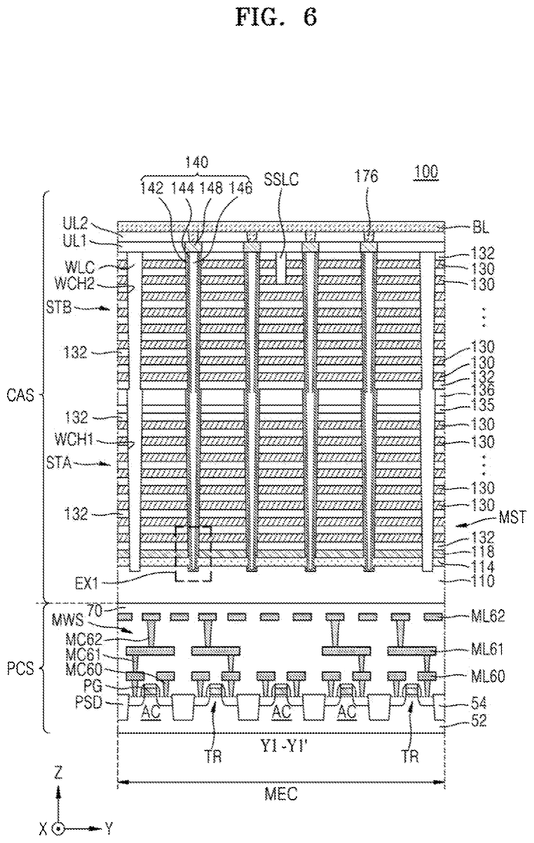

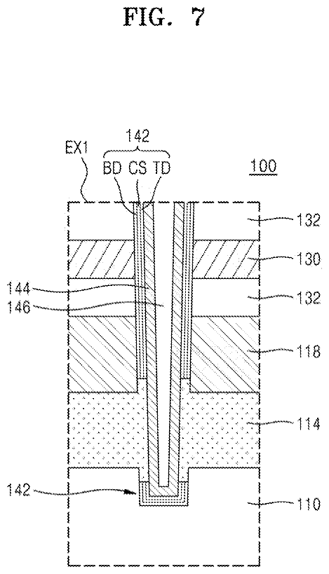

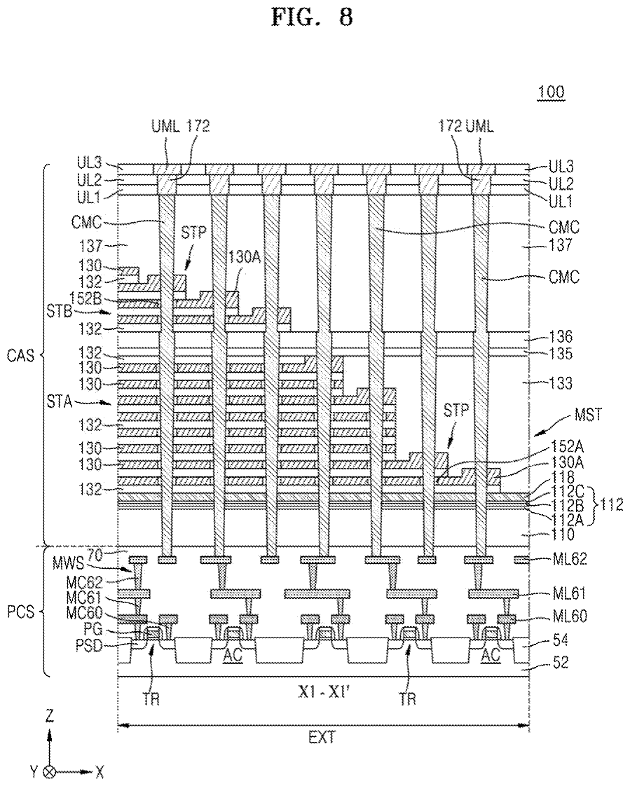

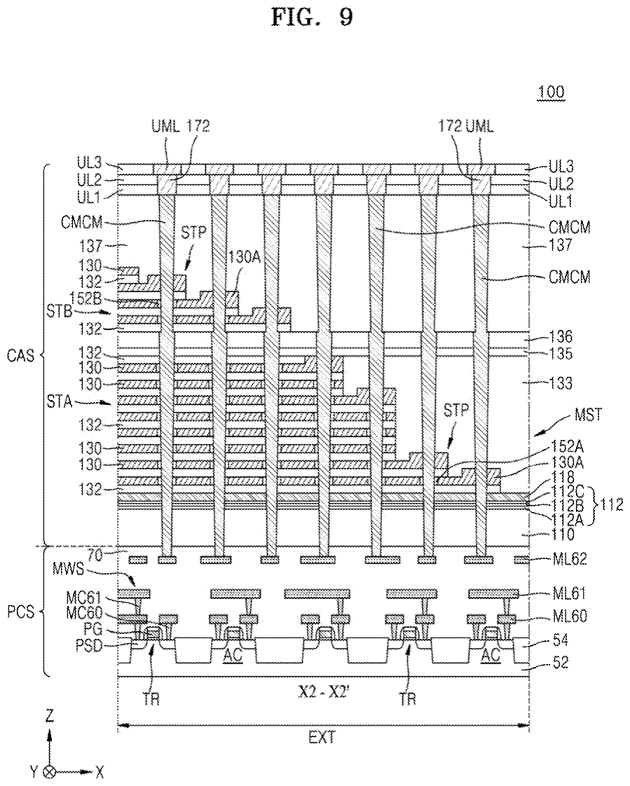

FIG. 5 shows a vertical non-volatile memory device according to an example embodiment. FIG. 6 is a cross-sectional view taken along line Y1-Y1′ of FIG. 5. FIG. 7 is a view showing an enlarged portion “EX1” of FIG. 6 according to an example embodiment. FIG. 8 is a cross-sectional view taken along line X1-X1′ of FIG. 5. FIG. 9 is a cross-sectional view taken along line X2-X2′ of FIG. 5.

In an implementation, FIG. 5 is a schematic plan view of some components of memory cell blocks BLK11 and BLK12. FIG. 6 is a cross-sectional view taken along line Y1-Y1′ of FIG. 5, and FIG. 7 is an enlarged cross-sectional view of some components included in a region indicated by “EX1” in FIG. 6.

FIG. 8 is a cross-sectional view taken along line X1-X1′ of FIG. 5. FIG. 9 is a cross-sectional view taken along line X2-X2′ of FIG. 5. The memory cell blocks BLK11 and BLK12 illustrated in FIG. 5 may be included in any one of the plurality of memory cell blocks BLK1, BLK2, BLK3, BLKn-1, BLKn illustrated in FIG. 4.

Referring to FIGS. 5 to 9, the vertical non-volatile memory device 100 may include the memory cell region MEC and the extension region EXT on the lower substrate 52 and the upper substrate 110. The vertical non-volatile memory device 100 may include the cell array structure CAS and the peripheral circuit structure PCS overlapping each other in the vertical direction (Z direction) on the lower substrate 52. The cell array structure CAS and the peripheral circuit structure PCS may be in the memory cell region MEC and the extension region EXT.

Here, the cell array structure CAS of the vertical non-volatile memory device 100 is described first. The cell array structure CAS may be in the memory cell region MEC and the extension region EXT. In the memory cell region MEC and the extension region EXT, a first stack STA at a first vertical level on the upper substrate 110 and a second stack STB at a second vertical level higher than the first vertical level on the upper substrate 110. As used herein, the term “vertical level” may refer to a distance in the vertical direction (Z direction or −Z direction) from the upper surface of the upper substrate 110.

Each of the first stack STA and the second stack STB may include the plurality of gate lines 130 overlapping each other in the vertical direction (Z direction) in the memory cell region MEC and a stepped connection portion STP in the extension region EXT and having a plurality of raised pads 130A integrally connected to the plurality of gate lines 130.

The gate line 130 may correspond to the word line WL described above with reference to FIGS. 1 and 3. The raised pad 130A may be a raised gate line pad. The raised pad 130A may be a raised word line pad. The first stack STA and the second stack STB may constitute the cell array structure CAS illustrated in FIG. 4.

As illustrated in FIG. 6, the first conductive plate 114 and the second conductive plate 118 may be on the upper substrate 110 in the memory cell region MEC, and as illustrated in FIGS. 8 and 9, an insulating plate 112 and a second conductive plate 118 may be on the upper substrate 110 in the extension region EXT. The memory stack structure MST including the first stack STA and the second stack STB may be on the second conductive plate 118 in the memory cell region MEC and the extension region EXT. In some embodiments, in the memory cell region MEC, each of the first conductive plate 114 and the second conductive plate 118 may function as a source region for supplying current to vertical memory cells included in the cell array structure CAS.

In some embodiments, the upper substrate 110 may include a semiconductor material such as polysilicon. Each of the first conductive plate 114 and the second conductive plate 118 may include a doped polysilicon layer, or a metal layer. The metal layer may include tungsten (W). In the memory stack structure MST, the plurality of gate lines 130 may extend parallel to each other in the horizontal direction and overlap each other in the vertical direction (Z direction). Each of the plurality of gate lines 130 may include metal, metal silicide, or a semiconductor doped with impurities. In an implementation, each of the plurality of gate lines 130 may include a metal such as tungsten, nickel, cobalt, or tantalum, a metal silicide such as tungsten silicide, nickel silicide, cobalt silicide, tantalum silicide, or doped polysilicon.

An insulating layer 132 may be between the second conductive plate 118 and the plurality of gate lines 130 and between each of the plurality of gate lines 130. An uppermost gate line 130 among the plurality of gate lines 130 in each of the first stack STA and the second stack STB may be covered with the insulating layer 132. The insulating layer 132 may include silicon oxide.

As illustrated in FIGS. 8 and 9, in the extension region EXT, the plurality of gate lines 130, the plurality of raised pads 130A, and a plurality of raised pads 130A, and the edge part of each of the plurality of gate lines 130 included in the first stack STA may be covered with a lower insulating block 133. In the extension region EXT, the plurality of gate lines 130, the plurality of raised pads 130A, and a plurality of raised pads 130A, and the edge part of each of the plurality of gate lines 130 included in the second stack STB may be covered with an upper insulating block 137. Each of the lower insulating block 133 and the upper insulating block 137 may include a silicon oxide layer.

A first intermediate insulating layer 135 and a second intermediate insulating layer 136 may be sequentially stacked on the first stack STA between the first stack STA and the second stack STB. Each of the first intermediate insulating layer 135 and the second intermediate insulating layer 136 may include a silicon oxide layer.

As illustrated in FIGS. 5 and 6, the plurality of word line cut structures WLC may extend long in the first horizontal direction (X direction) on the upper substrate 110 in the memory cell region MEC and the extension region EXT. A width of each of the plurality of gate lines 130 included in the memory cell blocks BLK11 and BLK12 in the second horizontal direction (Y direction) may be limited by the plurality of word line cut structures WLC.

Each of the plurality of word line cut structures WLC may include an insulating structure. In some embodiments, the insulating structure may include silicon oxide, silicon nitride, silicon oxynitride, or a low-k material. In an implementation, the insulating structure may include a silicon oxide layer, a silicon nitride layer, a SiON layer, a SiOCN layer, or a SiCN layer. In some embodiments, at least a part of the insulating structure may include an air gap. As used herein, the term “air” may refer to the atmosphere or other gases that may be present during a manufacturing process.

The plurality of gate lines 130 may be stacked to overlap each other in the vertical direction (Z direction) on the second conductive plate 118 between two adjacent word line cut structures WLC. The plurality of gate lines 130 may include a ground selection line, a plurality of word lines, and a string selection line.

In the plurality of gate lines 130, the upper two gate lines 130 may be separated in the second horizontal direction (Y direction) with a string selection line cut structure SSLC therebetween. Each of the two gate lines 130 separated from each other with the string selection line cut structure SSLC therebetween may constitute a string selection line.

FIG. 6 illustrates that one string selection line cut structure SSLC may be formed in one gate stack GS. In an implementation, at least two string selection line cut structures SSLC may be on one gate stack GS. The string selection line cut structure SSLC may be filled with an insulating layer.

In some embodiments, the string selection line cut structure SSLC may include an insulating layer including an oxide layer, or a nitride layer. In some embodiments, at least a part of the string selection line cut structure SSLC may include an air gap.

As illustrated in FIG. 6, the plurality of channel structures 140 may penetrate the plurality of gate lines 130, the plurality of insulating layers 132, the first intermediate insulating layer 135, the second intermediate insulating layer 136, the second conductive plate 118, and the first conductive plate 114 and extend in the vertical direction (Z direction) on the upper substrate 110 in the memory cell region MEC. The plurality of channel structures 140 may be spaced apart from each other with a certain gap therebetween in the first horizontal direction (X direction) and the second horizontal direction (Y direction). Each of the plurality of channel structures 140 may include a gate dielectric layer 142, a channel region 144, a filling insulating layer 146, and a drain region 148. Herein, each of the plurality of channel structures 140 may be referred to as a plug structure.

As illustrated in FIG. 7, the gate dielectric layer 142 may include a tunneling dielectric layer TD, a charge storage layer CS, and a blocking dielectric layer BD sequentially formed from the channel region 144 toward the gate line 130. Relative thicknesses of the tunneling dielectric layer TD, the charge storage layer CS, and the blocking dielectric layer BD those illustrated in FIG. 7 and may be variously modified.

The tunneling dielectric layer TD may include silicon oxide, hafnium oxide, aluminum oxide, zirconium oxide, or tantalum oxide. The charge storage layer CS may be a region in which electrons passing through the tunneling dielectric layer TD from the channel region 144 are stored, and may include silicon nitride, boron nitride, silicon boron nitride, or polysilicon doped with impurities. The blocking dielectric layer BD may include silicon oxide, silicon nitride, or a metal oxide having a higher permittivity than that of silicon oxide. The metal oxide may include hafnium oxide, aluminum oxide, zirconium oxide, or tantalum oxide.

As illustrated in FIGS. 6 and 7, the first conductive plate 114 may pass through a partial region of the gate dielectric layer 142 in the horizontal direction (X direction and/or Y direction) to contact the channel region 144. The thickness (size in the Z direction) of a part of the first conductive plate 114 vertically overlapping the gate dielectric layer 142 may be greater than the thickness (size in the Z direction) of a part of the first conductive plate 114 vertically overlapping the second conductive plate 118.

The gate dielectric layer 142 may include a part covering the sidewall of the channel region 144 at a level higher than the first conductive plate 114 and a part covering the bottom surface of the channel region 144 at a level lower than the first conductive plate 114. The channel region 144 may be spaced apart from the upper substrate 110 with the lowest portion of the gate dielectric layer 142 therebetween. A sidewall of the channel region 144 may contact the first conductive plate 114 and be electrically connected to the first conductive plate 114.

As illustrated in FIGS. 6 and 7, the channel region 144 may have a cylindrical shape. The channel region 144 may include doped polysilicon or undoped polysilicon. The filling insulating layer 146 may fill an internal space of the channel region 144. The filling insulating layer 146 may include an insulating material. In an implementation, the filling insulating layer 146 may include silicon oxide, silicon nitride, or silicon oxynitride. In some embodiments, the filling insulating layer 146 may be omitted. In this case, the channel region 144 may have a pillar structure having no internal space.

As illustrated in FIG. 6, the plurality of drain regions 148 may be insulated from each other by the first upper insulating layer UL1 covering the second stack STB. The plurality of drain regions 148 may include a doped polysilicon layer.

As illustrated in FIGS. 6, 8, and 9, the second upper insulating layer UL2 and the third upper insulating layer UL3 may be sequentially on the plurality of channel structures 140 and the first upper insulating layer UL1 in the memory cell region MEC and the extension region EXT. Each of the first upper insulating layer UL1, the second upper insulating layer UL2, and the third upper insulating layer UL3 may include an oxide layer, or a nitride layer.

As illustrated in FIGS. 5 and 6, a plurality of bit lines BL may be on the second upper insulating layer UL2 of the memory stack structure MST in the memory cell region MEC. The plurality of bit lines BL may extend parallel to each other in the second horizontal direction (Y direction). A space between each of the plurality of bit lines BL may be filled with the third upper insulating layer UL3 (see FIGS. 8 and 9). The drain region 148 of each of the plurality of channel structures 140 may be connected to the bit line BL through the contact plug 176 penetrating the second upper insulating layer UL2.

As illustrated in FIGS. 8 and 9, the insulating plate 112 and the second conductive plate 118 may be sequentially stacked on the upper substrate 110 in the extension region EXT. The insulating plate 112 may have a multilayer structure including a first insulating layer 112A, a second insulating layer 112B, and a third insulating layer 112C sequentially stacked on the upper substrate 110. In some embodiments, the first insulating layer 112A and the third insulating layer 112C may include a silicon oxide layer, and the second insulating layer 112B may include a silicon nitride layer.

In the extension region EXT, the raised pad 130A having a greater thickness in the vertical direction (Z direction) than other parts of the gate line 130 may be formed one end of each of the plurality of gate lines 130 included in the first stack STA and the second stack STB. The raised pad 130A may be integrally connected to an edge part of the gate line 130 farthest from the memory cell region MEC. FIGS. 6 and 8 illustrate only the raised pad 130A connected to one end of some of the plurality of gate lines 130, but another raised pad 130A integrally connected to another gate line 130 may be in another portion.

As illustrated in FIGS. 5, 8, and 9, a plurality of through type cell contact patterns CMC and a plurality of through type cell contact monitoring patterns CMCM may be in the extension region EXT. Each of the plurality of through type cell contact monitoring patterns CMCM may be a pattern for monitoring the plurality of through type cell contact patterns CMC by using an electron beam inspection device.

The plurality of through type cell contact monitoring patterns CMCM may be apart from the plurality of through type cell contact patterns CMC. Each of the plurality of through type cell contact monitoring patterns CMCM may be a pattern used for monitoring a horizontal contact defect (or a horizontal connection defect, or a horizontal connection failure) between the plurality of through type cell contact patterns CMC and the raised pad 130A by using the electron beam inspection device.

Each of the plurality of through type cell contact patterns CMC and the plurality of through type cell contact monitoring patterns CMCM may be electrically connectable to one raised pad 130A selected from among the plurality of raised pads 130A included in the first stack STA and the second stack STB. Herein, the plurality of through type cell contact patterns CMC and the plurality of through type cell contact monitoring patterns CMCM may be referred to as a plug structure.

Some through type cell contact patterns CMC selected from among the plurality of through type cell contact patterns CMC and some through type cell contact monitoring patterns CMCM selected from among the plurality of through type cell contact monitoring patterns CMCM may be spaced apart from the stepped connection portion STP included in the second stack STB in the horizontal direction (X direction in FIG. 5).

Each of some of the plurality of through type cell contact patterns CMC and some of the plurality of through type cell contact monitoring patterns CMCM may be configured to penetrate the stepped connection portion STP included in the first stack STA, the lower insulating block 133, the first intermediate insulating layer 135, the second intermediate insulating layer 136, and the upper insulating block 137 in the vertical direction (Z direction) and to be electrically connectable to one raised pad 130A selected from among the plurality of raised pads 130A included in the first stack STA.

Each of the others of the plurality of through type cell contact patterns CMC and the others of the plurality of through type cell contact monitoring patterns CMCM may be configured to penetrate the stepped connection portion STP included in the second stack STB in the vertical direction (Z direction) and to be electrically connectable to one raised pad 130A selected from among the plurality of raised pads 130A included in the second stack STB.

As illustrated in FIGS. 8 and 9, each of the plurality of through type cell contact patterns CMC and the plurality of through type cell contact monitoring patterns CMCM may penetrate at least some of the plurality of gate lines 130 and the plurality of insulating layers 132. Each of the plurality of through type cell contact patterns CMC and the plurality of through type cell contact monitoring patterns CMCM may be in a hole penetrating at least one of the plurality of gate lines 130.

Each of the plurality of through type cell contact patterns CMC and the plurality of through type cell contact monitoring patterns CMCM may be connected to one gate line 130 selected from among the plurality of gate lines 130, and may not be connected to the other gate lines 130 except for the selected one gate line 130. Each of the plurality of through type cell contact patterns CMC and the plurality of through type cell contact monitoring patterns CMCM may contact the raised pad 130A of one gate line 130 selected from among the plurality of gate lines 130, and may be connected to the selected one gate line 130 through the raised pad 130A.

In some embodiments, each of the plurality of through type cell contact patterns CMC and the plurality of through type cell contact monitoring patterns CMCM may include tungsten, titanium, tantalum, copper, aluminum, titanium nitride, tantalum nitride, or tungsten nitride.

Each of the plurality of through type cell contact patterns CMC and the plurality of through type cell contact monitoring patterns CMCM may be horizontally spaced apart from the other gate lines 130 except for the selected one gate line 130. In the first stack STA, a first insulating ring 152A may be between each of the plurality of through type cell contact patterns CMC and the plurality of through type cell contact monitoring patterns CMCM and the other gate line 130 not connected thereto.

In the second stack STB, a second insulating ring 152B may be between each of the plurality of through type cell contact patterns CMC and the plurality of through type cell contact monitoring patterns CMCM and the other gate line 130 not connected thereto. In some embodiments, the first insulating ring 152A and the second insulating ring 152B may include silicon oxide.

As illustrated in FIGS. 8 and 9, the upper insulating block 137 in the extension region EXT may be covered by the first upper insulating layer UL1 and the second upper insulating layer UL2. Each of the plurality of through type cell contact patterns CMC and the plurality of through type cell contact monitoring patterns CMCM may be connected to one of a plurality of upper wiring layers UML through a contact plug 172 penetrating the first upper insulating layer UL1 and the second upper insulating layer UL2. The plurality of upper wiring layers UML may be on the same vertical level as the plurality of bit lines BL in the memory cell region MEC. A space between each of the plurality of upper wiring layers UML may be filled with a third upper insulating layer UL3.

The uppermost surface of each of the plurality of through type cell contact patterns CMC and the plurality of through type cell contact monitoring patterns CMCM may extend at substantially the same vertical level. In some embodiments, each of the plurality of contact plugs 172, the plurality of contact plugs 176, the plurality of upper wiring layers UML, and the plurality of bit lines BL may include tungsten, titanium, tantalum, copper, aluminum, titanium nitride, tantalum nitride, or tungsten nitride.

Next, as described above, the vertical non-volatile memory device 100 may include the peripheral circuit structure PCS on the cell array structure CAS. Here, the peripheral circuit structure PCS is described in more detail.

The peripheral circuit structure PCS may include the lower substrate 52, a plurality of peripheral circuits on the lower substrate 52, and a multilayer wiring structure MWS for interconnecting the plurality of peripheral circuits or connecting the plurality of peripheral circuits to components of the memory cell region MEC.

The lower substrate 52 may be made of a semiconductor substrate. In an implementation, the lower substrate 52 may include Si, Ge, or SiGe. An active region AC may be defined on the lower substrate 52 by a device isolation layer 54. A plurality of transistors TR constituting the plurality of peripheral circuits may be on the active region AC. Each of the plurality of transistors TR may include a gate PG and a plurality of ion injection regions PSD in the active region AC on both sides of the gate PG. Each of the plurality of ion injection regions PSD may constitute a source region or a drain region of the transistor TR.

In some embodiments, the plurality of peripheral circuits included in the peripheral circuit structure PCS may include, a row decoder, a page buffer, a data input/output circuit, a control logic, or a CSL driver.

The multilayer wiring structure MWS included in the peripheral circuit structure PCS may include a plurality of peripheral circuit wiring layers ML60, ML61, and ML62 and a plurality of peripheral circuit contacts MC60, MC61, and MC62. At least some of the plurality of peripheral circuit wiring layers ML60, ML61, and ML62 may be electrically connectable to the transistor TR. The plurality of peripheral circuit contacts MC60, MC61, and MC62 may be configured to interconnect some selected from among the plurality of transistors TR and the plurality of peripheral circuit wiring layers ML60, ML61, and ML62.

FIGS. 6 and 8 illustrate that the multilayer wiring structure MWS may have three wiring layers in the vertical direction (Z direction). In an implementation, the multilayer wiring structure MWS may have two wiring layers or four or more wiring layers.

Each of the plurality of peripheral circuit wiring layers ML60, ML61, and ML62 and the plurality of peripheral circuit contacts MC60, MC61, and MC62 may include metal, conductive metal nitride, or metal silicide. In an implementation, each of the plurality of peripheral circuit wiring layers ML60, ML61, and ML62 and the plurality of peripheral circuit contacts MC60, MC61, and MC62 may include a conductive material such as tungsten, molybdenum, titanium, cobalt, tantalum, nickel, tungsten silicide, titanium silicide, cobalt silicide, tantalum silicide, or nickel silicide.

The plurality of transistors TR and the multilayer wiring structure MWS included in the peripheral circuit structure PCS may be covered with an interlayer insulating layer 70. The interlayer insulating layer 70 may include silicon oxide, SiON, or SiOCN.

As illustrated in FIG. 6, the upper substrate 110 may be on the peripheral circuit structure PCS in the memory cell region MEC of the cell array structure CAS, and the first conductive plate 114, the second conductive plate 118, the first stack STA, and the second stack STB may be sequentially stacked on the upper substrate 110.

As illustrated in FIG. 8, the upper substrate 110 may be on the peripheral circuit structure PCS in the extension region EXT of the cell array structure CAS, and the insulating plate 112, the second conductive plate 118, the first stack STA, and the second stack STB may be sequentially stacked on the upper substrate 110.

As illustrated in FIG. 8, a plurality of through openings 420H penetrating the upper substrate 110, the insulating plate 112, and the second conductive plate 118 may be in a partial region of the extension region EXT. Each of the plurality of through openings 420H may be filled with an insulating plug 420. The plurality of through openings 420H may be in positions overlapping a partial region of the peripheral circuit structure PCS in the vertical direction (Z direction). The insulating plug 420 may include a silicon oxide layer, or a silicon nitride layer.

In the extension region EXT, each of the plurality of through type cell contact patterns CMC may be configured to extend to the peripheral circuit structure PCS through the through opening 420H and be electrically connected to one wiring layer selected from among the plurality of peripheral circuit wiring layers ML60, ML61, and ML62. In an implementation, each of the plurality of through type cell contact patterns CMC may be electrically connected to the uppermost peripheral circuit wiring layer ML62 closest to the cell array structure CAS among the peripheral circuit wiring layers ML60, ML61, and ML62.

Each of the plurality of through type cell contact patterns CMC may be connected to at least one peripheral circuit selected from among the plurality of peripheral circuits through the multilayer wiring structure MWS included in the peripheral circuit structure PCS.

As illustrated in FIG. 9, each of the plurality of cell contact monitoring patterns CMCM extends to the peripheral circuit structure PCS through the through opening 420H in the extension region EXT, but may not be connected to the plurality of peripheral circuit wiring layers ML60 and ML61. In an implementation, each of the plurality of cell contact monitoring patterns CMCM may be floating without being connected to the peripheral circuit wiring layer ML61 located at the bottom of the peripheral circuit wiring layers ML60, ML61, and ML62.

As described above, each of the plurality of cell contact monitoring patterns CMCM may be floating without being connected to the peripheral circuit wiring layers ML60 and ML61, thereby easily monitoring a horizontal contact defect (or a horizontal connection defect, or a horizontal connection failure) between the plurality of through type cell contact patterns CMC and the raised pad 130A by using an electron beam inspection device.

In an implementation, when the plurality of cell contact monitoring patterns CMCM are connected to both the peripheral circuit wiring layers ML60 and ML61 and the raised pad 130A, it may be difficult to monitor a horizontal contact defect (or failure) between the through type cell contact pattern CMC and the raised pad 130A when using the electron beam inspection device.

On the other hand, when the plurality of cell contact monitoring patterns CMCM are floating without being connected to the peripheral circuit wiring layers ML61 and ML62, a horizontal contact defect (or a horizontal connection defect) between the plurality of through type cell contact patterns CMC and the raised pad 130A may be easily monitored when using the electron beam inspection device.

In other words, when the plurality of cell contact monitoring patterns CMCM are floating without being connected to the peripheral circuit wiring layers ML61 and ML62, the cell contact monitoring pattern CMCM may monitor only a horizontal contact defect (or a horizontal connection defect) between the through type cell contact pattern CMC and the raised pad 130A.

In an implementation, when the horizontal contact of the cell contact monitoring pattern CMCM is normal, the volume of a conductor of the cell contact monitoring pattern CMCM may be large. When the horizontal contact of the cell contact monitoring pattern CMCM is defective, the volume of the conductor of the cell contact monitoring pattern CMCM may be small. The horizontal contact defect (or failure) of the cell contact monitoring pattern CMCM may be monitored by detecting an image obtained by the electron beam inspection device according to the volume of the conductor of the cell contact monitoring pattern CMCM.

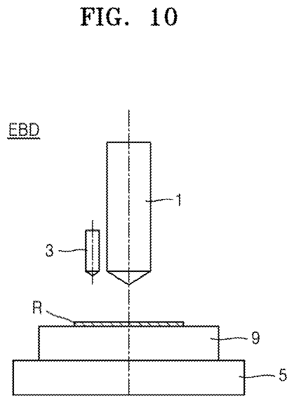

FIG. 10 is a diagram showing an electron beam inspection device according to an example embodiment. In an implementation, an electron beam inspection device EBD may include an electron beam inspection unit 1, an aiming device 3, a table 5, and an aiming device 12. The electron beam inspection unit 1 may be a scanning electron microscope in the form of an electron beam barrel. The electron beam inspection unit 1 may generate an electron beam to impact a specific region R of the surface of an object 9 to be inspected (e.g., the lower substrate (52 in FIGS. 6, 8, and 9 on which the vertical non-volatile memory device is formed).

The electron beam inspection unit 1 may collect and detect signals such as secondary electrons and backscattered electrons generated when the specific region R (e.g., the cell contact monitoring pattern CMCM of FIG. 9) of the object 9 to be inspected is impacted. The electron beam inspection unit 1 may amplify signals such as secondary electrons and backscattered electrons and then determine whether the object 9 to be inspected has a defect, e.g., a contact defect or a separation defect described below.

The aiming device 3 may be, e.g., an optical microscope. The aiming device 3 may determine the position of the object 9 to be inspected in the coordinate system of the electron beam inspection device EBD by collecting images of the object 9 to be inspected.

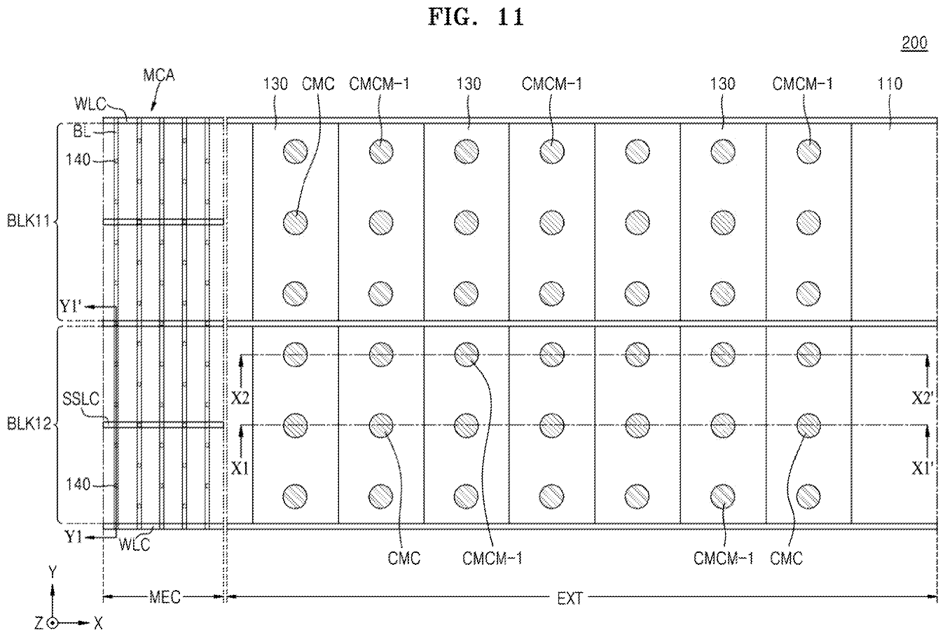

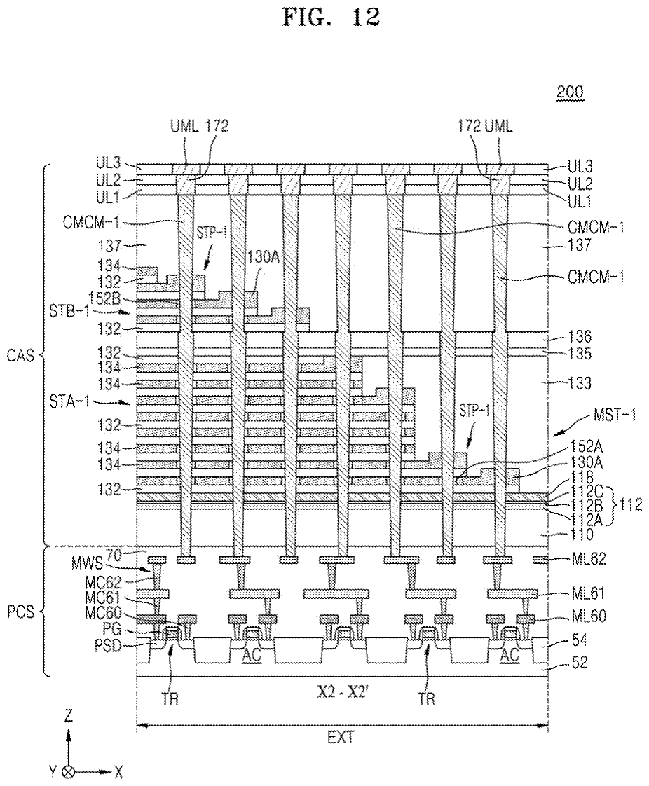

FIGS. 11 and 12 are detailed diagrams illustrating important components of a vertical non-volatile memory device according to an embodiment.

In an implementation, the vertical non-volatile memory device 200 of FIGS. 11 and 12 may be similar to the vertical non-volatile memory device 100 of FIGS. 5 to 9 except that the vertical non-volatile memory device 200 may include a through type cell contact monitoring pattern CMCM-1.

FIG. 11 is a plan view showing components of the memory cell blocks BLK11 and BLK12 of FIG. 4. FIG. 12 is a cross-sectional view taken along line X2-X2′ of FIG. 11.

A cross-sectional view taken along line Y1-Y1′ of FIG. 11 may be the same as that of FIG. 6. A cross-sectional view taken along line X1-X1′ of FIG. 11 may be the same as that of FIG. 8. In FIGS. 11 and 12, the descriptions given in FIGS. 5 to 9 are briefly provided or omitted.

The vertical non-volatile memory device 200 may include the memory cell region MEC and the extension region EXT on the lower substrate 52 and the upper substrate 110. The vertical non-volatile memory device 200 may include the cell array structure CAS and the peripheral circuit structure PCS overlapping each other in the vertical direction (Z direction) on the lower substrate 52. The cell array structure CAS and the peripheral circuit structure PCS may be in the memory cell region MEC and the extension region EXT.

As illustrated in FIG. 11, the plurality of through type cell contact patterns CMC and the plurality of through type cell contact monitoring patterns CMCM-1 may be in the extension region EXT. Each of the plurality of through type cell contact monitoring patterns CMCM-1 may be a pattern for monitoring the plurality of through type cell contact patterns CMC by using an electron beam inspection device. The plurality of through type cell contact monitoring patterns CMCM-1 may be in a second part of the extension region EXT.

Each of the plurality of through type cell contact monitoring patterns CMCM-1 may be a pattern used to monitor a vertical contact defect (or a vertical connection defect) between the plurality of through type cell contact patterns CMC and the peripheral circuit wiring layers ML60, ML61, and ML62 of the peripheral circuit structure PCS by using the electron beam inspection device.

The cell array structure CAS may include a plurality of memory stack structures MST-1. Each of the plurality of memory stack structures MST-1 may include a plurality of insulating layers 132 and a plurality of sacrificial insulating lines 134 that are alternately stacked in the vertical direction (Z direction).

In the cell array structure CAS, a first stack STA-1 may be on a first vertical level on the upper substrate 110 and a second stack STB-1 may be disposed at a second vertical level higher than the first vertical level on the upper substrate 110.

Each of the first stack STA-1 and the second stack STB-1 may include the plurality of insulating layers 132 and the plurality of sacrificial insulating layers 134 alternately stacked in the vertical direction (Z direction) in the memory cell region MEC. The first stack STA-1 and the second stack STB-1 may be in a state prior to displacing the plurality of sacrificial insulating lines 134 with gate lines when the vertical non-volatile memory device 200 is manufactured.

When the plurality of insulating layers 132 are silicon oxide layers, the plurality of sacrificial insulating lines 134 may be silicon nitride layers. The first stack STA-1 and the second stack STB-1 may include a stepped connection portion STP-1 in the extension region EXT and having a plurality of raised insulating pads 130B integrally connected to the plurality of sacrificial insulating lines 134. The stepped connection portion STP-1 may be an insulating structure.

Each of the plurality of through type cell contact monitoring patterns CMCM-1 in the extension region EXT may penetrate the stepped connection portion STP-1 having the plurality of raised insulating pads 130B included in the first stack STA-1, the lower insulating block 133, the first intermediate insulating layer 135, the second intermediate insulating layer 136, the stepped connection portion STP-1 having the plurality of raised insulating pads 130B included in the second stack STB-1, and the upper insulating block 137 in the vertical direction (Z direction).

In the extension region EXT, each of the plurality of through type cell contact monitoring patterns CMCM-1 may not be electrically connected to the raised insulating pad 130B but may be physically only thereto. In the extension region EXT, each of the plurality of through type cell contact monitoring patterns CMCM-1 may be electrically and physically separated from the gate line 130.

In addition, each of the plurality of through type cell contact monitoring patterns CMCM-1 in the extension region EXT may be configured to extend to the peripheral circuit structure PCS through the through opening 420H and to be electrically connected to one wiring layer selected from among the plurality of peripheral circuit wiring layers ML60, ML61, and ML62.

In an implementation, the plurality of through type cell contact monitoring patterns CMCM-1 may be electrically connected to the uppermost peripheral circuit wiring layer ML62 closest to the cell array structure CAS among the peripheral circuit wiring layers ML60, ML61, and ML62.

Each of the plurality of through type cell contact monitoring patterns CMCM-1 may be connected to at least one peripheral circuit selected from among the plurality of peripheral circuits through the multilayer wiring structure MWS included in the peripheral circuit structure PCS.

As illustrated in FIG. 12, in the extension region EXT, the plurality of cell contact monitoring patterns CMCM-1 may be physically connected to the raised insulating pad 130B and floating without being electrically connected thereto (i.e., electrically floating). In addition, in the extension region EXT, each of the plurality of cell contact monitoring patterns CMCM-1 may be electrically connected to the peripheral circuit wiring layers ML60, ML61, and ML62 of the peripheral circuit structure PCS through through-openings 420H.

In an implementation, each of the plurality of cell contact monitoring patterns CMCM-1 may be electrically connected to the peripheral circuit wiring layer ML62 located on top of the peripheral circuit wiring layers ML60, ML61, and ML62.

As described above, each of the plurality of cell contact monitoring patterns CMCM-1 may be electrically connected to the peripheral circuit wiring layers ML60, ML61, and ML62, thereby easily monitoring a vertical contact defect (or a vertical connection defect) between the plurality of through type cell contact patterns CMC and the circuit wiring layers ML62 by using an electron beam inspection device.

In other words, the plurality of cell contact monitoring patterns CMCM-1 may be physically connected to the raised insulating pad 130B horizontally and may be electrically connected to the peripheral circuit wiring layers ML60, ML61, and ML62 vertically. The plurality of cell contact monitoring patterns CMCM-1 may easily monitor a vertical contact defect (or a vertical connection defect) between the plurality of through type cell contact patterns CMC and the peripheral circuit wiring layer ML62 by using the electron beam inspection device.

In an implementation, when the vertical contact of the cell contact monitoring pattern CMCM-1 is normal, the volume of a conductor of the cell contact monitoring pattern CMCM-1 may be large. When the vertical contact of the cell contact monitoring pattern CMCM-1 is defective, the volume of the conductor of the cell contact monitoring pattern CMCM may be small. The vertical contact defect of the cell contact monitoring pattern CMCM-1 may be monitored by detecting an image obtained by the electron beam inspection device according to the volume of the conductor of the cell contact monitoring pattern CMCM-1.

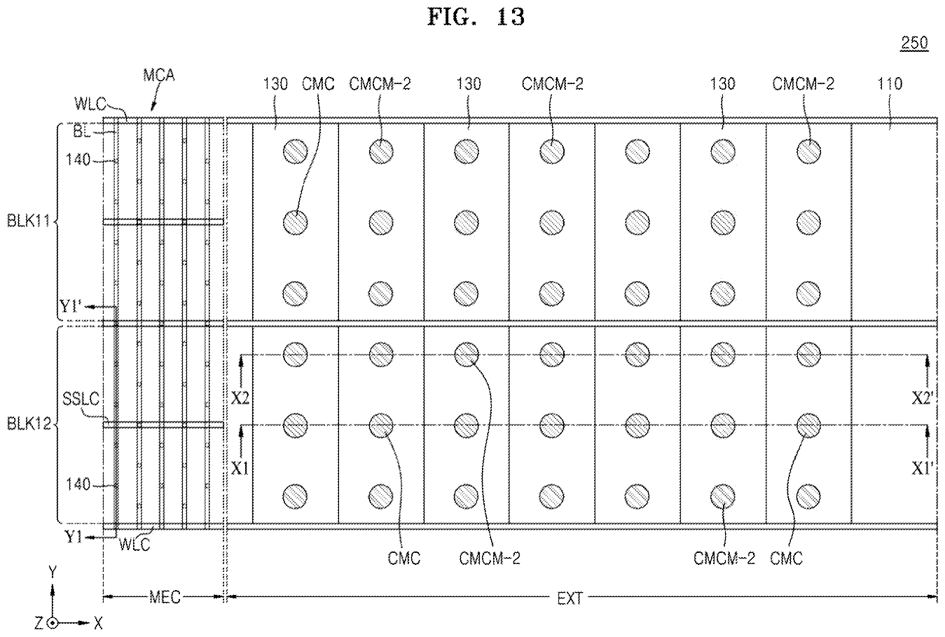

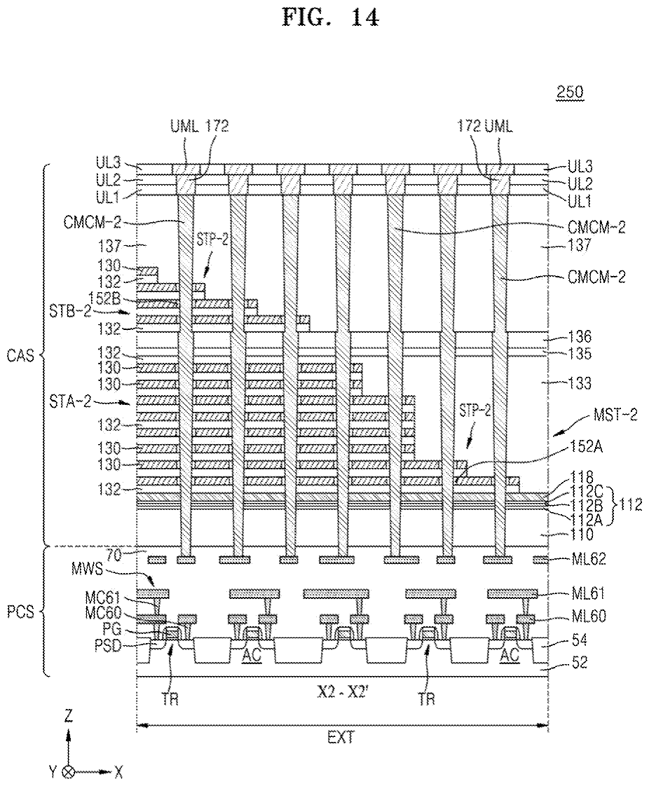

FIGS. 13 and 14 are detailed diagrams illustrating important components of a vertical non-volatile memory device according to an embodiment.

In an implementation, a vertical non-volatile memory device 250 of FIGS. 13 and 14 may be similar to the vertical non-volatile memory device 100 of FIGS. 5 to 9 except that the vertical non-volatile memory device 250 may include a through type cell contact monitoring pattern CMCM-2.

FIG. 13 is a plan view showing components of the memory cell blocks BLK11 and BLK12 of FIG. 4. FIG. 14 is a cross-sectional view taken along line X2-X2′ of FIG. 13.

A cross-sectional view taken along line Y1-Y1′ of FIG. 13 may be the same as that of FIG. 6. A cross-sectional view taken along line X1-X1′ of FIG. 13 may be the same as that of FIG. 8. In FIGS. 13 and 14, the descriptions given in FIGS. 5 to 9 briefly provided or omitted.

The vertical non-volatile memory device 250 may include the memory cell region MEC and the extension region EXT on the lower substrate 52 and the upper substrate 110. The vertical non-volatile memory device 250 may include the cell array structure CAS and the peripheral circuit structure PCS overlapping each other in the vertical direction (Z direction) on the lower substrate 52. The cell array structure CAS and the peripheral circuit structure PCS may be in the memory cell region MEC and the extension region EXT.

As illustrated in FIG. 13, the plurality of through type cell contact patterns CMC and the plurality of through type cell contact monitoring patterns CMCM-2 may be in the extension region EXT. Each of the plurality of through type cell contact monitoring patterns CMCM-2 may be a pattern for monitoring the plurality of through type cell contact patterns CMC using an electron beam inspection device. The plurality of through type cell contact monitoring patterns CMCM-2 may be in a third part of the extension region EXT.

Each of the plurality of through type cell contact monitoring patterns CMCM-2 may be a pattern used to monitor a horizontal separation defect between the plurality of through type cell contact patterns CMC and the gate line 130 of the cell array structure CAS by using the electron beam inspection device.

The cell array structure CAS may include a plurality of memory stack structures MST-2. Each of the plurality of memory stack structures MST-2 may include the plurality of gate lines 130 stacked to overlap each other in the vertical direction (Z direction) and the plurality of insulating layers 132 located between the gate lines 130.

In the cell array structure CAS, a first stack STA-2 may be on a first vertical level on the upper substrate 110 and a second stack STB-2 may be disposed at a second vertical level higher than the first vertical level on the upper substrate 110. Each of the first stack STA-1 and the second stack STB-1 may include the plurality of insulating layers 132 and the plurality of gate lines 130 alternately stacked in the vertical direction (Z direction) in the memory cell region MEC.

The first stack STA-2 and the second stack STB-2 may be in a state in which the plurality of sacrificial insulating lines (134 of FIG. 12) are displaced with the gate lines 130 without forming the raised insulating pad (130B of FIG. 12) when the vertical non-volatile memory device 250 is manufactured.

The first stack STA-1 and the second stack STB-1 may include a stepped connection portion STP-2 in the extension region EXT and integrally connected to the plurality of gate lines 130. Unlike the above, the stepped connection portion STP-2 does not include the raised pad 130A.

Each of the plurality of through type cell contact monitoring patterns CMCM-2 in the extension region EXT may penetrate the stepped connection portion STP-2 included in the first stack STA-2, the lower insulating block 133, the first intermediate insulating layer 135, the second intermediate insulating layer 136, the stepped connection portion STP-2 included in the second stack STB-2, and the upper insulating block 137 in the vertical direction (Z direction).

In the extension region EXT, each of the plurality of through type cell contact monitoring patterns CMCM-2 may not be electrically connected to the gate line 130 by the first insulating ring 152A and the second insulating ring 152B. In addition, each of the plurality of through type cell contact monitoring patterns CMCM-2 in the extension region EXT may extend to the peripheral circuit structure PCS through the through opening 420H but may not be connected to the plurality of peripheral circuit wiring layers ML60 and ML61.

In an implementation, each of the plurality of through type cell contact monitoring patterns CMCM-2 may be floating without being connected to the peripheral circuit wiring layer ML61 located at the bottom of the peripheral circuit wiring layers ML60, ML61, and ML62.

As illustrated in FIG. 14, in the extension region EXT, each of the plurality of through type cell contact monitoring patterns CMCM-2 may be floating without being connected to the gate line 130 by the first insulating ring 152A and the second insulating ring 152B.

In addition, each of the plurality of through type cell contact monitoring patterns CMCM-2 may be floating without being connected to the peripheral circuit wiring layers ML60 and ML61, thereby easily monitoring a horizontal separation defect between the plurality of through type cell contact patterns CMC and the gate line 130 of the cell array structure CAS by using an electron beam inspection device.

In other words, the plurality of cell contact monitoring patterns CMCM-2 may be horizontally insulated from the gate line 130 and vertically electrically insulated from the peripheral circuit wiring layers ML60 and LM61. The plurality of cell contact monitoring patterns CMCM-2 may easily monitor the horizontal separation defect between the plurality of through type cell contact patterns CMC and the gate line 130 of the cell array structure CAS by using the electron beam inspection device.

In an implementation, when the horizontal separation of the cell contact monitoring pattern CMCM-2 is normal, the volume of a conductor of the cell contact monitoring pattern CMCM-2 may be small. When the horizontal separation of the cell contact monitoring pattern CMCM-2 is defective, the volume of the conductor of the cell contact monitoring pattern CMCM-2 may be large. The vertical contact defect of the cell contact monitoring pattern CMCM-1 may be monitored by detecting an image obtained by the electron beam inspection device according to the volume of the conductor of the cell contact monitoring pattern CMCM-2.

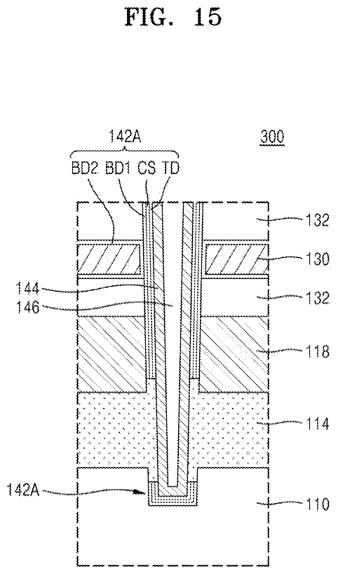

FIG. 15 is a view showing an enlarged portion “EX1” of FIG. 6 according to an example embodiment. In an implementation, a vertical non-volatile memory device 300 may be an enlarged cross-sectional configuration of a portion corresponding to the region indicated by “EX1” in FIG. 6. In FIG. 15, the descriptions given in FIGS. 5 to 9 are briefly provided or omitted.

The vertical non-volatile memory device 300 may have substantially the same configuration as the vertical non-volatile memory device 100 described with reference to FIGS. 5 to 9. The vertical non-volatile memory device 300 may include a gate dielectric layer 142A instead of the gate dielectric layer 142.

The gate dielectric layer 142A may have substantially the same configuration as the gate dielectric layer 142 described with reference to FIGS. 5 to 9. The gate dielectric layer 142A may include a first blocking dielectric layer BD1 and a second blocking dielectric layer BD2 instead of the blocking dielectric layer BD. The first blocking dielectric layer BD1 may extend parallel to the channel region 144, and the second blocking dielectric layer BD2 may surround the gate line 130.

Each of the first blocking dielectric layer BD1 and the second blocking dielectric layer BD2 may include silicon oxide, silicon nitride, or metal oxide. In an implementation, the first blocking dielectric layer BD1 may include silicon oxide, and the second blocking dielectric layer BD2 may include a metal oxide having a higher dielectric constant than that of the silicon oxide layer. The metal oxide may include hafnium oxide, aluminum oxide, zirconium oxide, or tantalum oxide.

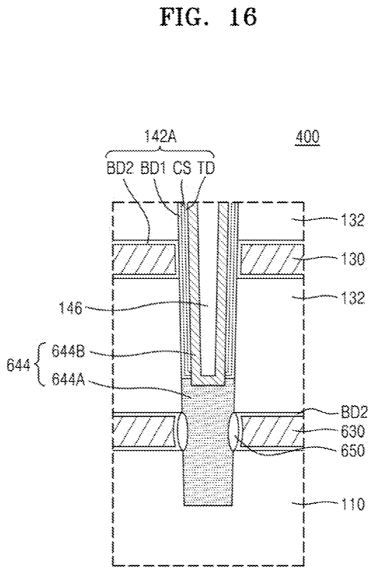

FIG. 16 is a view showing an enlarged portion “EX1” of FIG. 6 according to an example embodiment. In an implementation, a vertical non-volatile memory device 400 may be an enlarged cross-sectional configuration of a portion corresponding to the region indicated by “EX1” in FIG. 6. In FIG. 16, the descriptions given in FIGS. 5 to 9 are briefly provided or omitted. The vertical non-volatile memory device 400 may have substantially the same configuration as the vertical non-volatile memory device 100 described with reference to FIGS. 5 to 9.

The vertical non-volatile memory device 400 may include the gate dielectric layer 142A instead of the gate dielectric layer 142. The gate dielectric layer 142A may include the first blocking dielectric layer BD1 and the second blocking dielectric layer BD2. More detailed configurations of the first blocking dielectric layer BD1 and the second blocking dielectric layer BD2 are described with reference to FIG. 15.

The vertical non-volatile memory device 400 may include a ground selection gate line 630 between the substrate 110 and the plurality of gate lines 130. Also, the vertical non-volatile memory device 400 may include a channel region 644 instead of the channel region 144. The channel region 644 may include a lower semiconductor pattern 644A and an upper semiconductor pattern 644B. The lower semiconductor pattern 644A may include a semiconductor material layer epitaxially grown from the substrate 110. The lower semiconductor pattern 644A may have a pillar shape, and an upper surface of the lower semiconductor pattern 644A may be located above an upper surface of the lowest ground select gate line 630. The upper semiconductor pattern 644B and the lower semiconductor pattern 644A may contact each other. Each of the lower semiconductor patterns 644A may include Si, or Ge. The upper semiconductor pattern 644B may have substantially the same configuration as described with respect to the channel region 144 with reference to FIGS. 5 to 9.

The ground select gate line 630 may be surrounded by the second blocking dielectric layer BD2. A gate dielectric layer 650 may be between the ground selection gate line 630 and the lower semiconductor pattern 644A. The second blocking dielectric layer BD2 may be between the gate dielectric layer 650 and the ground selection gate line 630.

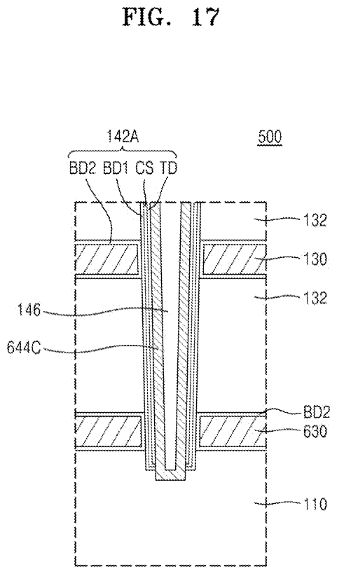

FIG. 17 is a view showing an enlarged portion “EX1” of FIG. 6 according to an example embodiment. In an implementation, a vertical non-volatile memory device 500 may be an enlarged cross-sectional configuration of a portion corresponding to the region indicated by “EX1” in FIG. 6. In FIG. 17, the descriptions given in FIGS. 5 to 9 are briefly provided or omitted. The vertical non-volatile memory device 500 may have substantially the same configuration as the vertical non-volatile memory device 100 described with reference to FIGS. 5 to 9.

The vertical non-volatile memory device 500 may not include the lower semiconductor pattern 644A illustrated in FIG. 16. The vertical non-volatile memory device 500 may include a channel region 644C instead of the channel region 144 described above. A lower end of the channel region 644C may contact the upper substrate 110. The gate dielectric layer 142A may be between the channel region 644C and the ground selection gate line 630. A more detailed configuration of the channel region 644C may be substantially the same as that described with respect to the channel region 144 with reference to FIGS. 5 to 9.

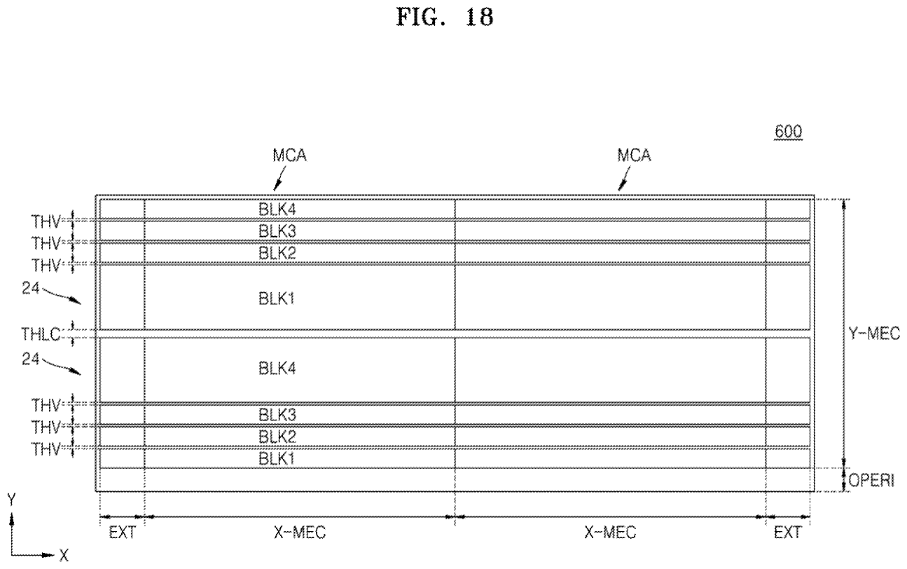

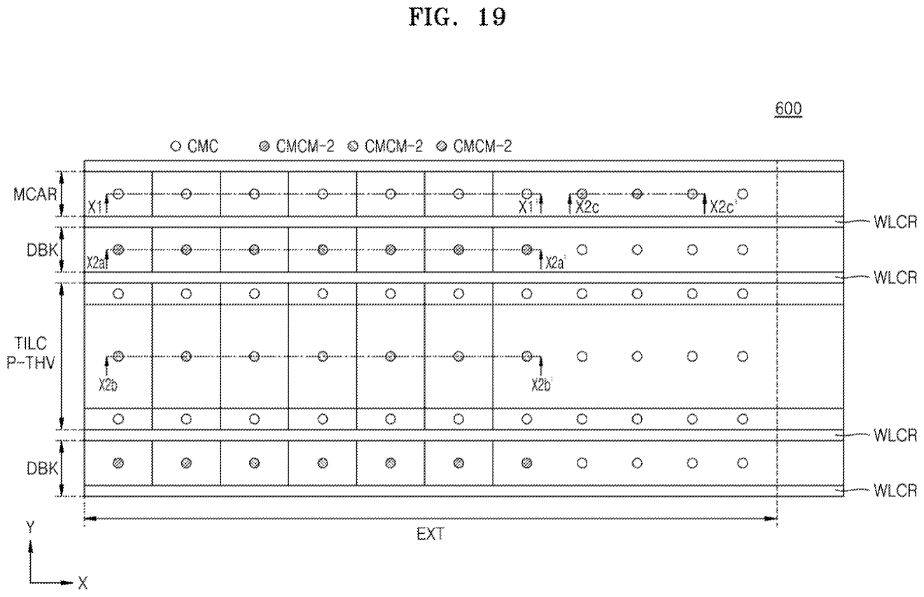

FIGS. 18 and 19 are detailed diagrams illustrating important components of a vertical non-volatile memory device according to an embodiment. In an implementation, a vertical non-volatile memory device 650 of FIGS. 18 and 19 may be similar to the vertical non-volatile memory device 100 of FIGS. 5 to 9, the vertical non-volatile memory device 200 of FIGS. 11 and 12, and the vertical non-volatile memory device 250 of FIGS. 13 and 14, except that the vertical non-volatile memory device 650 may include all of the through type cell contact monitoring patterns CMCM, CMCM-1, and CMCM-2. In FIGS. 18 and 19, the descriptions given in FIGS. 5 to 9, 11 and 12, and 13 and 14 are briefly provided or omitted.

FIG. 18 is a partial plan view showing a vertical non-volatile memory device according to an example embodiment. As shown in FIG. 18, the vertical non-volatile memory device 600 may include the plurality of tiles 24. A tile cut region TILC may be between the tiles 24 in the X direction. The tile cut region TILC may be a region where a through via connecting an upper wiring of the vertical non-volatile memory device 600 and an internal peripheral circuit is disposed.

Each of the tiles 24 may include the memory cell blocks BLK1 to BLK4. Each of the memory cell blocks BLK1 to BLK4 may include the memory cell array MCA. The tiles 24 and the memory cell array MCA have been described above, and thus, descriptions thereof are omitted.

The vertical non-volatile memory device 600 may include the X-direction memory cell region X-MEC disposed in the X direction and the Y-direction memory cell region Y-MEC disposed in the Y direction. The extension regions EXT may be on both sides of the X-direction memory cell region X-MEC. The peripheral circuit region PERI may be on one side of the tile 24 in the Y direction.

In the vertical memory device 600, a through via arrangement region PTHV may be between the memory cell blocks BLK to BLK4 in the X direction. The through via arrangement region THV may be a region where a through via connecting a bit line to a page buffer circuit is disposed.

FIG. 19 is a partial plan view showing an extension region “EXT” of FIG. 18 according to an example embodiment. The extension region EXT may include a memory cell array region MCAR, a dummy block region DBK, the tile cut region TILC, the through via arrangement region PTHV, and a word line cut region WLCR.

The vertical memory device 600 may include the through type cell contact pattern CMC and the through type cell contact monitoring patterns CMCM, CMCM-1, and CMCM-2. A cross-sectional view taken along line X1-X1′ of FIG. 19 may be the same as that of FIG. 8. The through type cell contact pattern CMC may be in the memory cell array region MCAR of the extension region EXT.

A cross-sectional view taken along line X2a-X2a′ of FIG. 19 may correspond to FIG. 9. The through type cell contact monitoring pattern CMCM may be a pattern for monitoring the through type cell contact pattern CMC by using an electron beam inspection device.

The cell contact monitoring pattern CMCM may be a pattern for monitoring a horizontal contact defect (or a horizontal connection defect) between the through type cell contact pattern (CMC in FIG. 9) and the raised pad (130A in FIG. 9). The cell contact monitoring pattern CMCM may be in the dummy block region DBK.

A cross-sectional view taken along line X2b-X2b′ of FIG. 19 may correspond to FIG. 12. The through type cell contact monitoring pattern CMCM-1 may be a pattern for monitoring the through type cell contact pattern CMC by using the electron beam inspection device. The cell contact monitoring pattern CMCM-1 may be a pattern used to monitor a vertical contact defect (or a vertical connection defect) between the through type cell contact pattern (CMC in FIG. 12) and the peripheral circuit wiring layers ML60, ML61, and ML62 in FIG. 12) of the peripheral circuit structure (PCS in FIG. 12) by using the electron beam inspection device. The cell contact monitoring pattern CMCM-1 may be in the tile cut region TILC and the through via arrangement region PTHV.

A cross-sectional view taken along line X2c-X2c′ of FIG. 19 may correspond to FIG. 14. The through type cell contact monitoring pattern CMCM-2 may be a pattern for monitoring the through type cell contact pattern CMC by using the electron beam inspection device. In FIG. 19, only three through type cell contact monitoring patterns CMCM-2 are shown for convenience.

The cell contact monitoring pattern CMCM-2 may be a pattern used to monitor a horizontal separation defect between the through type cell contact pattern (CMC in FIG. 14) and the gate line (130 in FIG. 14) of the cell array structure (CAS in FIG. 14) by using the electron beam inspection device.

The cell contact monitoring pattern CMCM-2 may be in a region where the raised pad is removed. The cell contact monitoring pattern CMCM-2 may be in an intersection region of the X-direction memory cell region X-MEC and the Y-direction memory cell region Y-MEC.

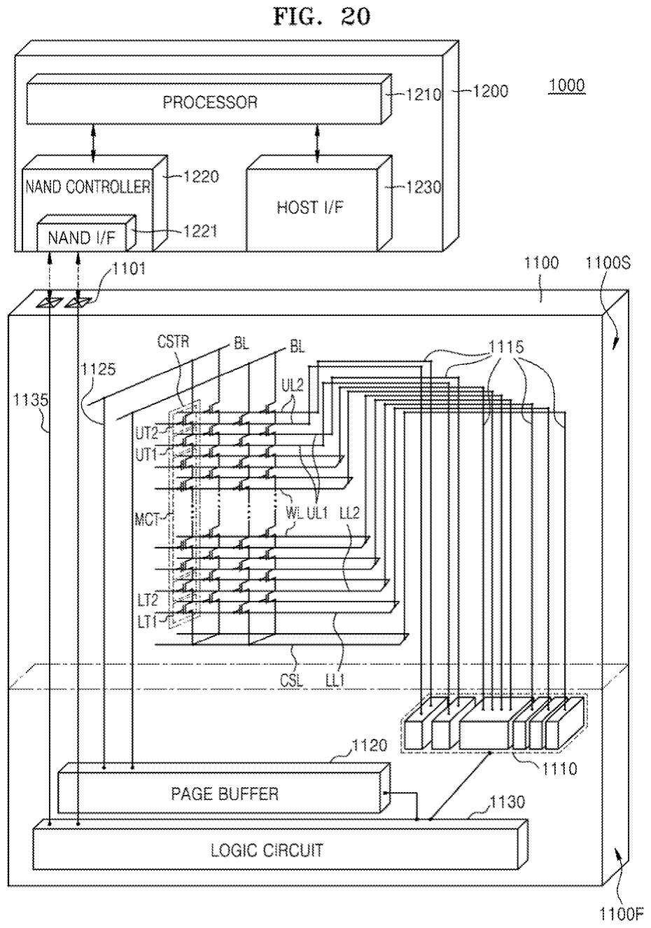

FIG. 20 is a diagram showing an electronic system including a vertical non-volatile memory device according to an example embodiment. In an implementation, the electronic system 1000 according to an embodiment may include a semiconductor device 1100 and a controller 1200 electrically connected to the semiconductor device 1100. The electronic system 1000 may be a storage device including one or a plurality of semiconductor devices 1100 or an electronic device including the storage device. The electronic system 1000 may be, e.g., a solid state drive (SSD) device including at least one semiconductor device 1100, a universal serial bus (USB), a computing system, a medical device, or a communication device.

The semiconductor device 1100 may be a non-volatile semiconductor device. In an implementation, the semiconductor device 1100 may be a NAND flash semiconductor device that is the vertical non-volatile semiconductor device described above. The semiconductor device 1100 may include a first structure 1100F and a second structure 1100S on the first structure 1100F.

In some embodiments, the first structure 1100F may be next to the second structure 1100S. The first structure 1100F may be a peripheral circuit structure including a row decoder 1110, a page buffer 1120, and a logic circuit 1130. The second structure 1100S may be a memory cell structure including the bit line BL, the common source line CSL, a plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may be variously modified.

In some embodiments, the upper transistors UT1 and UT2 may include string select transistors, and the lower transistors LT1 and LT2 may include ground select transistors. The plurality of gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2.

The common source line CSL, the plurality of gate lower lines LL1 and LL2, the plurality of word lines WL, and the plurality of gate upper lines UL1 and UL2 may be electrically connected to the decoder circuit 1110 through a first connection wiring 1115 extending from the first structure 1100F to the second structure 1100S. The plurality of bit lines BL may be electrically connected to the page buffer 1120 through a plurality of second connection wirings 1125 extending from the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 through the input/output pad 1101 electrically connected to the logic circuit 1130. The input/output pad 1101 may be electrically connected to the logic circuit 1130 through an input/output connection wiring 1135 extending from the first structure 1100F to the second structure 1100S.

The controller 1200 may include a processor 1210, a NAND controller 1220, and a host interface 1230. According to some embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to a certain firmware, and may access the semiconductor device 1100 by controlling the NAND controller 1220. The NAND controller 1220 may include a NAND interface 1221 processing communication with the semiconductor device 1100. Through the NAND interface 1221, a control command for controlling the semiconductor device 1100, data to be written to the plurality of memory cell transistors MCT of the semiconductor device 1100, and data to be read from the plurality of memory cell transistors MCT of the semiconductor device 1100 may be transmitted. The host interface 1230 may provide a communication function between the electronic system 1000 and an external host. When receiving a control command from an external host through the host interface 1230, the processor 1210 may control the semiconductor device 1100 in response to the control command.

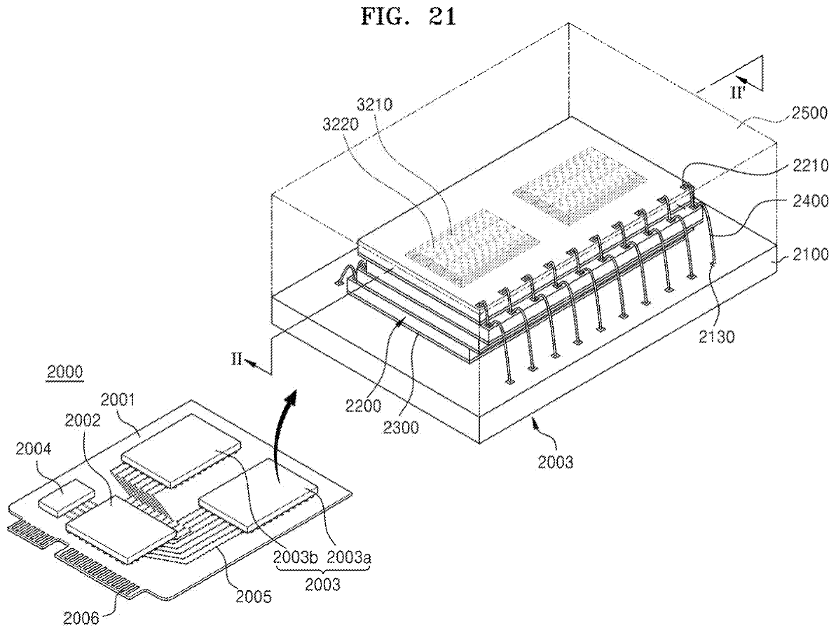

FIG. 21 is a perspective view showing an electronic system including a vertical non-volatile memory device according to an example embodiment. In an implementation, an electronic system 2000 according to an embodiment may include a main board 2001, a controller 2002 mounted on the main board 2001, one or more semiconductor packages 2003, and a DRAM 2004. The semiconductor package 2003 and the DRAM 2004 may be connected to the controller 2002 by a plurality of wiring patterns 2005 on the main board 2001.

The main board 2001 may include a connector 2006 including a plurality of pins combined with an external host. The number and arrangement of the plurality of pins in the connector 2006 may vary depending on a communication interface between the electronic system 2000 and the external host. In some embodiments, the electronic system 2000 may communicate with the external host according to any one of interfaces such as Universal Serial Bus (USB), Peripheral Component Interconnect Express (PCI-Express), Serial Advanced Technology Attachment (SATA), or M-Phy for Universal Flash Storage (UFS). In some embodiments, the electronic system 2000 may operate by power supplied from the external host through the connector 2006. The electronic system 2000 may further include a power management integrated circuit (PMIC) distributing power supplied from the external host to the controller 2002 and the semiconductor package 2003. The controller 2002 may write data to or read data from the semiconductor package 2003 and may improve the operating speed of the electronic system 2000.

The DRAM 2004 may be a buffer memory reducing a speed difference between the semiconductor package 2003 that is a data storage space, and the external host. The DRAM 2004 included in the electronic system 2000 may operate as a kind of cache memory, and may provide a space temporarily storing data in a control operation on the semiconductor package 2003. When the electronic system 2000 includes the DRAM 2004, the controller 2002 may further include a DRAM controller controlling the DRAM 2004, in addition to a NAND controller controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 on a lower surface of each of the plurality of semiconductor chips 2200, a connection structure 2400 electrically connecting the plurality of semiconductor chips 2200 and the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 20. Each of the plurality of semiconductor chips 2200 may include a plurality of gate stacks 3210 and a plurality of channel structures 3220. Each of the plurality of semiconductor chips 2200 may include the vertical non-volatile memory devices 100, 200, 250, 300, 400, 500, and 600 described above.

In some embodiments, the connection structure 2400 may be a bonding wiring electrically connecting the input/output pad 2210 and the package upper pad 2130. Accordingly, in the first and second semiconductor packages 2003a and 2003b, the plurality of semiconductor chips 2200 may be electrically connected to each other by a bonding wiring method, and may be electrically connected to the package upper pad 2130 of the package substrate 2100. According to some embodiments, in the first and second semiconductor packages 2003a and 2003b, the plurality of semiconductor chips 2200 may be electrically connected to each other by a connection structure including a through silicon via (TSV) instead of the bonding wiring type connection structure 2400.

In some embodiments, the controller 2002 and the plurality of semiconductor chips 2200 may be included in one package. In an embodiment, the controller 2002 and the plurality of semiconductor chips 2200 may be mounted on a separate interposer substrate different from the main board 2001, and the controller 2002 and the plurality of semiconductor chips 2200 may be connected to each other by a wiring on the interposer substrate.

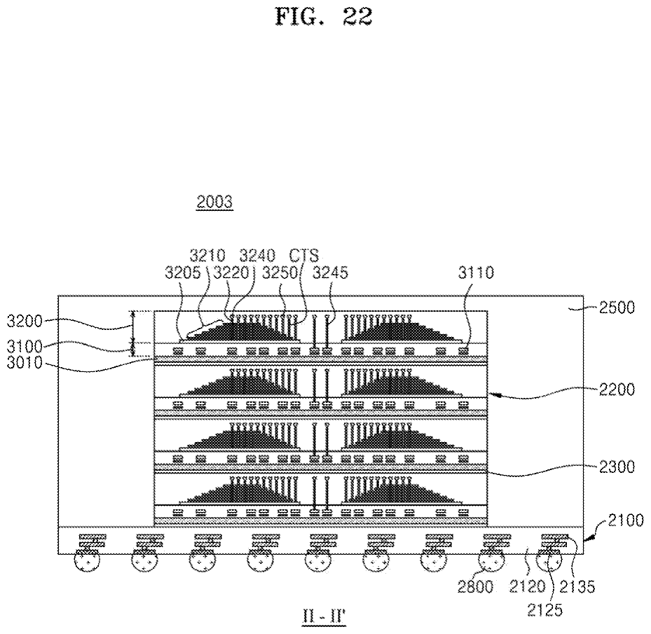

FIG. 22 is a cross-sectional view taken along line II-II′ of FIG. 21. In an implementation, in a semiconductor package 2003, the package substrate 2100 may be a printed circuit board. The package substrate 2100 may include a package substrate body portion 2120, a plurality of package upper pads 2130 (see FIG. 21) on an upper surface of the package substrate body portion 2120, a plurality of lower pads 2125 arranged on or exposed through a lower surface of the package substrate body portion 2120, and a plurality of internal wirings 2135 electrically connecting the plurality of package upper pads 2130 and the plurality of lower pads 2125 in the package substrate body portion 2120.

The plurality of package upper pads 2130 may be electrically connected to the plurality of connection structures 2400. The plurality of lower pads 2125 may be connected to the plurality of wiring patterns 2005 on the main board 2001 of the electronic system 2000 shown in FIG. 21 through a plurality of conductive bumps 2800.

Each of the plurality of semiconductor chips 2200 may include the vertical non-volatile memory devices 100, 200, 250, 300, 400, and 500 described above. Each of the plurality of semiconductor chips 2200 may include a semiconductor substrate 3010 and a first structure 3100 and a second structure 3200 sequentially stacked on the semiconductor substrate 3010. The first structure 3100 may include a peripheral circuit region including a plurality of peripheral wirings 3110. The second structure 3200 may include a common source line 3205, a gate stack 3210 on the common source line 3205, a channel structure 3220 penetrating the gate stack 3210, and a bit line 3240 electrically connected to the channel structure 3220.

Each of the plurality of semiconductor chips 2200 may include a through wiring 3245 electrically connected to the plurality of peripheral wirings 3110 of the first structure 3100 and extending into the second structure 3200. The through wiring 3245 may be outside the gate stack 3210.

In some embodiments, the semiconductor package 2003 may further include a through wiring penetrating the gate stack 3210. Each of the plurality of semiconductor chips 2200 may further include input/output pads (2210 in FIG. 21) electrically connected to the plurality of peripheral wirings 3110 of the first structure 3100.

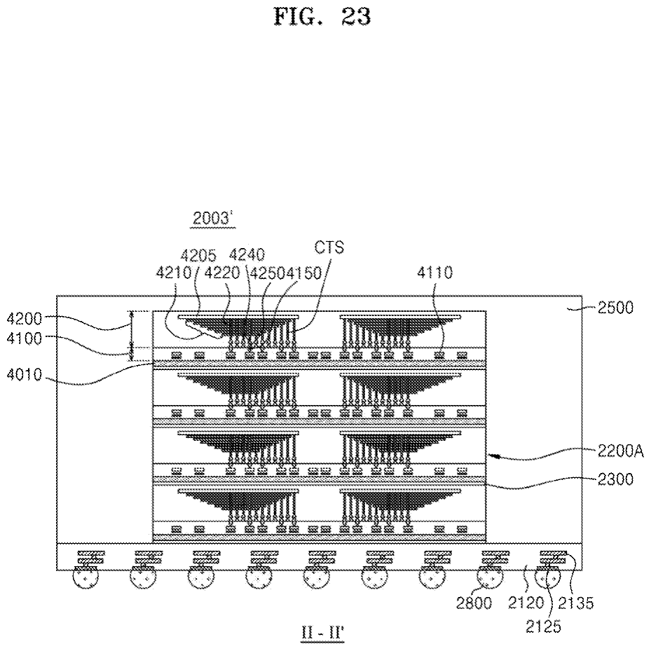

FIG. 23 is a cross-sectional view taken along line II-II′ of FIG. 21. In FIG. 23, the configuration taken along line II-II′ of FIG. 21 is shown in more detail.

In an implementation, a semiconductor package 2003′ has substantially the same configuration as the semiconductor package 2003 described with reference to FIG. 22. However, the semiconductor package 2003′ may include a plurality of semiconductor chips 2200A. Each of the plurality of semiconductor chips 2220A may include the vertical non-volatile memory devices 100, 200, 250, 300, 400, and 500 described above.

Each of the plurality of semiconductor chips 2200A may include a semiconductor substrate 4010, a first structure 4100 on the semiconductor substrate 4010, and a second structure 4200 bonded to the first structure 4100 by a wafer bonding method on the first structure 4100.

The first structure 4100 may include a peripheral circuit region including a peripheral wiring 4110 and a plurality of first junction structures 4150. The second structure 4200 may include a common source line 4205, a gate stack 4210 between the common source line 4205 and the first structure 4100, and a channel structure 4220 penetrating the gate stack 4210.

Also, each of the plurality of semiconductor chips 2200A may include a plurality of second junction structures 4250 electrically connected to the plurality of word lines (WL of FIG. 14) of the gate stack 4210 respectively. In an implementation, each of the plurality of second junction structures 4250 may be electrically connected to a bit line 4240 electrically connected to the channel structure 4220, the channel structure 4220, through a contact structure CTS electrically connected to the word line (WL in FIG. 20, and the word line (WL in FIG. 14).

The plurality of first bonding structures 4150 of the first structure 4100 and the plurality of second bonding structures 4250 of the second structure 4200 may be bonded while contacting each other. Bonded parts of the plurality of first junction structures 4150 and the plurality of second junction structures 4250 may include, e.g., copper (Cu).

The plurality of semiconductor chips 2200 illustrated in FIG. 22 and the plurality of semiconductor chips 2200A illustrated in FIG. 23 may be electrically connected to each other by the plurality of connection structures 2400 (see FIG. 21) in the form of bonding wirings. In some embodiments, the plurality of semiconductor chips 2200 illustrated in FIG. 21 and the plurality of semiconductor chips 2200A illustrated in FIG. 23 may be electrically connected to each other by a connection structure including a through electrode TSV.

By way of summation and review, a vertical non-volatile memory device having three-dimensionally arranged memory cells instead of two-dimensionally arranged memory cells has been proposed. It is very difficult to reliably manufacture the vertical non-volatile memory device having three-dimensionally arranged memory cells. A vertical non-volatile memory device in which three-dimensionally arranged memory cells are reliably manufactured is disclosed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made.

What is claimed is:

1. A vertical non-volatile memory device, comprising:
a memory cell region including a plurality of gate lines overlapping each other in a vertical direction, and an insulating layer insulating the plurality of gate lines from each other in the vertical direction;
an extension region on one side of the memory cell region, the extension region including a plurality of stepped connection portions having a plurality of raised pads integrally connected to each of the plurality of gate lines;
a peripheral circuit structure in a lower portion of the memory cell region and the extension region, the peripheral circuit structure including a peripheral circuit wiring layer;
a through type cell contact pattern in the extension region penetrating the plurality of gate lines, the insulating layer, and the plurality of stepped connection portions; and
a through type cell contact monitoring pattern in the extension region spaced from the through type cell contact pattern, the through type cell contact monitoring pattern monitoring the through type cell contact pattern.

2. The vertical non-volatile memory device as claimed in claim 1, wherein:
the through type cell contact pattern is electrically connected to the plurality of raised pads in a horizontal direction, and
the through type cell contact monitoring pattern is configured to detect a defect of a horizontal connection between the plurality of raised pads and the through type cell contact pattern.

3. The vertical non-volatile memory device as claimed in claim 1, wherein:
the through type cell contact pattern is electrically connected to the plurality of raised pads and the peripheral circuit wiring layer, and
the through type cell contact pattern is electrically and physically separated from the plurality of gate lines by an insulating ring.

4. The vertical non-volatile memory device as claimed in claim 1, wherein:
the through type cell contact monitoring pattern penetrates the plurality of gate lines, the insulating layer, and the plurality of stepped connection portions,
the through type cell contact monitoring pattern is electrically connected to the plurality of raised pads in a horizontal direction, and
the through type cell contact monitoring pattern is electrically floating with respect to the peripheral circuit wiring layer in the vertical direction.

5. The vertical non-volatile memory device as claimed in claim 1, wherein:
the extension region further includes a second portion including the plurality of stepped connection portions having the plurality of raised insulating pads integrally connected to each of a plurality of sacrificial insulating lines corresponding to the plurality of gate lines,
the through type cell contact pattern is electrically floating with respect to the raised insulating pad in a horizontal direction, and
the through type cell contact monitoring pattern is configured to detect a defect of a vertical connection between the through type cell contact pattern and the peripheral circuit wiring layer.

6. The vertical non-volatile memory device as claimed in claim 5, wherein:
the through type cell contact monitoring pattern penetrates the plurality of sacrificial insulating lines, the insulating layer, and the plurality of stepped connection portions,
the through type cell contact monitoring pattern is electrically floating with respect to the raised insulating pad in the horizontal direction, and
the through type cell contact monitoring pattern is electrically connected to the peripheral circuit wiring layer in the vertical direction.

7. The vertical non-volatile memory device as claimed in claim 5, wherein the through type cell contact monitoring pattern is electrically and physically separated from the plurality of sacrificial insulating lines by an insulating ring.

8. The vertical non-volatile memory device as claimed in claim 1, wherein:
the extension region further includes a third portion including the plurality of stepped connection portions integrally connected to each of the plurality of gate lines,
the through type cell contact pattern is separated from the plurality of gate lines in a horizontal direction, and
the through type cell contact monitoring pattern is configured to detect a defect of a horizontal separation between the through type cell contact pattern and the plurality of gate lines.

9. The vertical non-volatile memory device as claimed in claim 8, wherein:
the through type cell contact monitoring pattern penetrates the plurality of gate lines, the insulating layer, and the plurality of stepped connection portions,
the through type cell contact monitoring pattern is separated from the plurality of gate lines in the horizontal direction, and
the through type cell contact monitoring pattern is electrically floating with respect to the peripheral circuit wiring layer in the vertical direction.

10. The vertical non-volatile memory device as claimed in claim 8, wherein:
the through type cell contact monitoring pattern is electrically and physically separated from plurality of gate lines by an insulating ring.

11. A vertical non-volatile memory device, comprising:
a peripheral circuit structure including a peripheral circuit wiring layer;
a cell array structure on the peripheral circuit structure, the cell array structure including a memory cell region and an extension region,
wherein the memory cell region includes a plurality of gate lines overlapping each other in a vertical direction, and an insulating layer insulating the plurality of gate lines from each other in the vertical direction, the extension region being on one side of the memory cell region, the extension region including a plurality of stepped connection portions having a plurality of raised pads integrally connected to each of the plurality of gate lines;
a through type cell contact pattern in the extension region, the through type cell contact pattern penetrating the plurality of gate lines, the insulating layer, and the plurality of stepped connection portions; and
a through type cell contact monitoring pattern in the extension region away from the through type cell contact pattern, the through type cell contact monitoring pattern monitoring the through type cell contact pattern.

12. The vertical non-volatile memory device as claimed in claim 11, wherein:
the through type cell contact monitoring pattern penetrates the plurality of gate lines, the insulating layer, and the plurality of stepped connection portions,
the through type cell contact monitoring pattern is electrically connected to the plurality of raised pads in a horizontal direction, and
the through type cell contact monitoring pattern is electrically floating with respect to the peripheral circuit wiring layer in the vertical direction.

13. The vertical non-volatile memory device as claimed in claim 11, wherein:
the through type cell contact pattern is electrically connected to the plurality of raised pads and the peripheral circuit wiring layer, and
the through type cell contact pattern is electrically and physically separated from the plurality of gate lines by an insulating ring.

14. The vertical non-volatile memory device as claimed in claim 11, wherein:
the extension region further includes a second portion including the plurality of stepped connection portions having the plurality of raised insulating pads integrally connected to each of a plurality of sacrificial insulating lines corresponding to the plurality of gate lines,
the through type cell contact monitoring pattern penetrates the plurality of sacrificial insulating lines, the insulating layer, and the plurality of stepped connection portions,
the through type cell contact monitoring pattern is electrically floating with respect to the raised insulating pad in a horizontal direction, and
the through type cell contact monitoring pattern is electrically connected to the peripheral circuit wiring layer in the vertical direction.

15. The vertical non-volatile memory device as claimed in claim 14, wherein the through type cell contact monitoring pattern is electrically and physically separated from the plurality of sacrificial insulating lines by an insulating ring.

16. The vertical non-volatile memory device as claimed in claim 11, wherein:
the extension region further includes a third portion including the plurality of stepped connection portions integrally connected to each of the plurality of gate lines,
the through type cell contact monitoring pattern penetrates the plurality of gate lines, the insulating layer, and the plurality of stepped connection portions,
the through type cell contact monitoring pattern is separated from the plurality of gate lines in a horizontal direction, and
the through type cell contact monitoring pattern is electrically floating with respect to the peripheral circuit wiring layer in the vertical direction.

17. A vertical non-volatile memory device, comprising:
a peripheral circuit structure on a lower substrate, the peripheral circuit structure including a peripheral circuit wiring layer;
a cell array structure on the peripheral circuit structure, the cell array structure including a memory cell region and an extension region on an upper substrate,
wherein the memory cell region includes a plurality of gate lines overlapping each other in a vertical direction on the upper substrate, and an insulating layer insulating the plurality of gate lines from each other in the vertical direction, the extension region being on one side of the memory cell region, the extension region including a plurality of stepped connection portions having a plurality of raised pads integrally connected to each of the plurality of gate lines;
a through type cell contact pattern in the extension region, the through type cell contact pattern penetrating the plurality of gate lines, the insulating layer, the plurality of stepped connection portions, and the upper substrate; and
a through type cell contact monitoring pattern in the extension region away from the through type cell contact pattern, the through type cell contact monitoring pattern monitoring the through type cell contact pattern.

18. The vertical non-volatile memory device as claimed in claim 17, wherein:
the through type cell contact monitoring pattern penetrates the plurality of gate lines, the insulating layer, the plurality of stepped connection portions, and the upper substrate,
the through type cell contact monitoring pattern is electrically connected to the plurality of raised pads in a horizontal direction, and
the through type cell contact monitoring pattern is electrically floating with respect to the peripheral circuit wiring layer in the vertical direction.

19. The vertical non-volatile memory device as claimed in claim 17, wherein:
the extension region further includes a second portion including the plurality of stepped connection portions having the plurality of raised insulating pads integrally connected to each of the plurality of sacrificial insulating lines corresponding to the plurality of gate lines,
the through type cell contact monitoring pattern penetrates a plurality of sacrificial insulating lines, the insulating layer, the plurality of stepped connection portions, and the upper substrate,
the through type cell contact monitoring pattern is electrically floating with respect to the raised insulating pad in a horizontal direction, and
the through type cell contact monitoring pattern is electrically connected to the peripheral circuit wiring layer in the vertical direction.

20. The vertical non-volatile memory device as claimed in claim 17, wherein:
the extension region further includes a third portion including the plurality of stepped connection portions integrally connected to each of the plurality of gate lines,
the through type cell contact monitoring pattern penetrates the plurality of gate lines, the insulating layer, the plurality of stepped connection portions, and the upper substrate,
the through type cell contact monitoring pattern is separated from the plurality of gate lines in a horizontal direction, and
the through type cell contact monitoring pattern is electrically floating with respect to the peripheral circuit wiring layer in the vertical direction.
